(19) United States
(12) Patent Application Publication
(10) Pub. No.: US 2024/0230972 A1
(43) Pub. Date: Jul. 11, 2024

(54) DAYTIME RADIATIVE DEVICE

(71) Applicants: CENTRE NATIONAL DE LA RECHERCHE SCIENTIFIQUE, Paris (FR); COMMISSARIAT À L'ENERGIE ATOMIQUE ET AUX ENERGIES ALTERNATIVES, Paris (FR); UNIVERSITÉ DE CAEN NORMANDIE, Caen (FR); ÉCOLE NATIONALE SUPÉRIEURE D'INGÉNIEURS DE CAEN, Caen (FR)

(72) Inventors: Julien CARDIN, Biéville-Beuville (FR); Ramzy DAOU, Caen (FR); Cédric FRILAY, Authie (FR); Fabrice GOURBILLEAU, Toulouse (FR); Jennnifer WEIMMERSKIRCH-AUBATIN, Valence (FR); Bryan HORCHOLLE, Regnéville sur Mer (FR)

(21) Appl. No.: 18/563,525

(22) PCT Filed: May 23, 2022
(86) PCT No.: PCT/EP2022/063924

§ 371 Date: Nov. 22, 2023

(30) Foreign Application Priority Data
May 24, 2021 (FR) FR2105377

(51) Int. Cl. G02B 5/20; C03C 17/34; C23C 14/06; C23C 14/08; C23C 14/10; C23C 14/35; C23C 14/54; C23C 14/58

(52) U.S. Cl. CPC G02B 5/208; C03C 17/3417; C03C 17/3441; C23C 14/0635; C23C 14/083; C23C 14/10; C23C 14/35; C23C 14/547; C23C 14/5873

(57) ABSTRACT

The invention relates to a daytime radiative cooling device comprising a reflective portion consisting of an alternating stack of layers A and layers B, said layers A consisting of at least one material A selected from among Nb₂O₅, TiO₂ and Ta₂O₅ and said layers B consisting of at least one material B selected from among SiO₂ and Al₂O₃. The invention also relates to a method for determining the reflective portion of a daytime radiative cooling device. Finally, the invention relates to a method for determining the emitting portion of a daytime radiative cooling device.

### DAYTIME RADIATIVE DEVICE

The invention relates to a daytime radiative device. The invention also relates to a method for determining the structure of a daytime radiative device.

The increase in the air-conditioning and refrigeration demand could break the promises and the objectives for countering global warming. Indeed, cooling the interior of a building is today carried out primarily by heat exchangers of the air-conditioning type. The global energy consumption for air-conditioning in buildings alone should increase by 33 times till 2100, with the increase in the revenues of the developing countries and the progress of urbanisation. In the middle of the 21^{st} century, more energy will be used for cooling than for heating. Air conditioners operate with electricity which is globally produced predominantly by the combustion of fossil fuels. Hence, current cooling solutions are in opposition with the objectives Of lowering greenhouse gases emissions that have been set during Bonn International Summit (COP23).

In response to this problem, daytime radiative passive coolers have been developed. Daytime radiative passive coolers are based on the principle of heat exchange with the space, which is an extremely cold environment. These devices represent a cooling solution that does not consume energy and therefore have a positive impact on the objectives of reducing greenhouse gas emissions.

When the electromagnetic radiation from the Sun arrives on Earth, part of the wavelengths of the spectrum is reflected and another part is absorbed by the terrestrial atmosphere. The electromagnetic radiation transports throughout the space a certain amount of energy with a certain spectral distribution. Also, the objective of the daytime radiative passive coolers is to reflect the most energetic waves passing through the terrestrial atmosphere and to emit a radiation that passes very well throughout the atmosphere in order to reach the space. Thus, as much heat from the Sun is returned in the space and partly in the atmosphere, and the heat received from the Earth is emitted into the space in the form of a radiation.

Thus, the wavelength range for which the reflection should be maximised corresponds to the spectral range of the solar spectrum passing throughout the atmosphere for which the luminance of the Sun is the most intense. It is comprised from 260 to 2,500 nm, in particular between 260 nm and 2,500 nm, and is represented by the solar luminance spectrum AM1.5. The designation AM1.5 refers to the mass of air encountered by the sunlight arriving at 45° at the surface of the Earth, AM1 corresponds to the air mass thickness of the atmosphere. The wavelength range for which the emission is to be maximised corresponds to the spectral range of the atmospheric transmission spectrum for which the transmission is the highest and the widest. This spectral range is called the atmospheric transparency window (ATW) and is comprised from 7,500 to 13,300 nm, in particular between 7,500 nm and 13,300 nm.

The document by A. P. Raman et al, Nature, 2014, 515, 540-54, describes a daytime radiative cooler comprising silver and hafnium. Despite the good reflection and emissivity performances of this device, its composition is based on rare and expensive metals, which prevents mass production needed to meet increasing air-conditioning needs. The materials are also sensitive to oxidation.

The documents by Gentle et al., Nano Lett. 2010, 10, 373-379 and Zhai et al., Science, 2017, 355, 1062-1066 propose daytime radiative coolers comprising polymeric materials that are unfortunately sensitive to photodestruction by the UV light during prolonged exposure to the Sun and to photo-oxidation by reaction with oxygen present in the air.

Moreover, the cooling performance of the devices presented hereinabove is limited by a partial overlap of the emitted wavelengths with the wavelengths of the atmospheric transparency window. Hence, this window is not exploited at its full potential.

The invention aims in particular to overcome these drawbacks of the prior art.

More particularly, an objective of the invention is to provide a daytime radiative cooling device with good reflection and emissivity performances, which is inexpensive to produce and which lasts over time.

Another objective of the invention is to provide a method for determining the structure of a daytime radiative cooling device.

Finally, an objective of the invention is to provide a method for manufacturing a daytime radiative cooling device.

To this end, an object of the invention is a daytime radiative cooling device comprising a reflective portion consisting of an alternating superposition of layers A and of layers B, said layers A consisting of at least one material A selected from among Nb₂O₅, TiO₂ and Ta₂O₅, said layers B consisting of at least one material B selected from among SiO₂ and Al₂O₃.

By “reflective portion”, it should be understood in the invention a portion having reflective properties for the wavelengths from 260 nm to 2,500 nm.

The Inventors have unexpectedly discovered that the alternating superposition of layers A consisting of at least one material A selected from among Nb₂O₅, TiO₂ and Ta₂O₅ and of layers B consisting of at least one material B selected from among SiO₂ and Al₂O₃ allowed obtaining a daytime radiative cooling device having good refrigeration performances. Such a device has a reflection performance for the wavelengths from 260 nm to 2,500 nm higher than 90% and has an emissivity performance for the wavelengths from 7,500 to 13,300 nm higher than 50%. Of course, during use thereof, the daytime device according to the invention must have access to the open sky. More particularly, during use thereof, the reflective portion is arranged:
at a normal angle of incidence (0°) for the reflecting solar radiation to obtain the best reflection performance, and
at a zenithal angle of 0° to obtain the best emissivity performances.

Furthermore, the device of the invention allows exploiting at 100% the wavelengths of the atmospheric transparency window, from 7,500 to 13,300 nm. The materials used in the radiative device according to the invention are advantageously inexpensive, are stable over time and are barely and even not sensitive to photo-destruction. Finally, the radiative device according to the invention advantageously has poor performances in terms of reflection and emission respectively outside each range considered hereinabove. This advantageously allows avoiding sending to the atmosphere wavelengths that it can absorb, which would lead to contributing to the greenhouse effect and therefore to global warming.

The material A of the invention corresponds to a material having an average value of the refractive index (n) for the wavelengths from 260 nm to 2,500 nm greater than 2, and an average value of the extinction coefficient (k) less than 0.15, for these same wavelengths. In this respect, the material A may be selected from among Nb₂O₅, TiO₂ and Ta₂O₅ (cf. FIGS. 12a, 14a and 15a).

The material B of the invention corresponds to a material having an average value of the refractive index n for the wavelengths from 260 nm to 2,500 nm lower than 1.7 and an average value of the extinction coefficient k for these wavelengths lower than 0.15 and/or an extinction coefficient k higher than 0.40 for at least one of the wavelengths of the ATW. In this respect, the material may be selected from among SiO₂ and Al₂O₃ (cf. FIG. 13a).

Thus, it is the specific combination of materials (A and B) having a strong contrast, i.e. a large difference in their respective refractive index over the spectral range from 250 nm to 2,500 nm which allows obtaining the substantial performances in terms of reflection of the reflective portion of the daytime radiative device according to the invention.

Furthermore, the absorption capacities of the material B for the wavelengths of the ATW allow obtaining the emissivity performances of the daytime radiative device according to the invention.

The upper layer, i.e. the one intended to be arranged at the top of the superposition of layers during use of the device, and the base layer, i.e. the one intended to be at the bottom of the superposition of layers, may be indifferently a layer B or a layer A.

The reflective portion may comprise an even or odd number of superposed layers.

According to an embodiment of the invention, at least two materials A are used to form the layers A, and at least two materials B are used to form the layers B. This aspect of the invention allows improving the performances of the reflective portion in terms of emissivity for the wavelengths in the ATW. In this embodiment, each layer consists of one single material. Indeed, mixing materials to form each layer A or B would lead to reflection performance problems.

According to an embodiment of the invention, all of the layers A consist of the same material A and/or all of the layers B consist of the same material B.

The reflective portion may have layers made of a material having one of the 21 compositions listed in the following table:

TABLE 1

| | |
|---|---|
| Layers A | Layers B |

| Comp. | Nb₂O₅ | TiO₂ | Ta₂O₅ | SiO₂ | Al₂O₃ |
|---|---|---|---|---|---|
| 1 | + | | | + | |
| 2 | | + | | + | |
| 3 | | | + | + | |
| 4 | + | + | | + | |
| 5 | + | | + | + | |
| 6 | | + | + | + | |
| 7 | + | + | + | + | |
| 8 | + | | | | + |
| 9 | | + | | | + |
| 10 | | | + | | + |
| 11 | + | + | | | + |
| 12 | + | | + | | + |
| 13 | | + | + | | + |
| 14 | + | + | + | | + |
| 15 | + | | | + | + |
| 16 | | + | | + | + |
| 17 | | | + | + | + |
| 18 | + | + | | + | + |
| 19 | + | | + | + | + |
| 20 | | + | + | + | + |
| 21 | + | + | + | + | + |

Each layer of the reflective portion may have any thickness. Preferably, the layers of the reflective portion have a thickness variability resulting in varied optical paths (δ) comparable to the wavelengths the reflection of which is desired. This aspect of the invention allows improving the reflection performance of the reflective portion.

The relationship between the optical path of a wave (δ) and the thickness of a layer (d) as a function of the refractive index (n) of the material forming said layer is given by the following formula:

$$δ = n \cdot d \qquad [ Math 1 ]$$

The maximum refractive index of material A varying from 3 to 4, with a variability of the thickness of the layers from 1 to 500 nm, optical paths ranging from 3 nm to 1,500 nm up to 2,000 nm are obtained, covering most of the wavelengths whose reflection is desired.

According to an embodiment of the invention, each layer A and each layer B has a respective and independent thickness from 1 to 1,750 nm. Thus, this thickness interval allows covering all of the wavelengths of the range of the spectrum (260 nm to 2,500 nm) the reflection of which is desired. Furthermore, this thickness interval allows obtaining daytime radiative cooling devices that can be made more easily and at a lower cost. Indeed, a layer thickness smaller than 1 nm is difficult to obtain, and a thickness beyond 1,750 nm increases the material costs without significantly increasing the performances of the device (for the aforementioned reasons).

According to an embodiment of the invention, the reflective portion comprises at least 70 layers. An increased number of layers allows obtaining better refrigeration performances. In particular, such a device has a reflection performance for the wavelengths from 260 nm to 2,500 nm higher than 90%. Thus, it is in particular included within the scope of the invention at least 70 layers, at least 71 layers, at least 72 layers, at least 73 layers, at least 74 layers, at least 75 layers, at least 76 layers, at least 77 layers, at least 78 layers, at least 79 layers, at least 80 layers, at least 81 layers, at least 82 layers, at least 83 layers, at least 84 layers, at least 85 layers, at least 86 layers, at least 87 layers, at least 88 layers, at least 89 layers, at least 90 layers, at least 91 layers, at least 92 layers, at least 93 layers, at least 94 layers, at least 95 layers, at least 96 layers, at least 97 layers, at least 98 layers, at least 99 layers, at least 100 layers, at least 101 layers, at least 102 layers, at least 103 layers, at least 104 layers, at least 105 layers, at least 106 layers, at least 107 layers, at least 108 layers, at least 109 layers, at least 110 layers, at least 111 layers, at least 112 layers, at least 113 layers, at least 114 layers, at least 115 layers, at least 116 layers, at least 117 layers, at least 118 layers, at least 119 layers, at least 120 layers, at least 121 layers, at least 122 layers, at least 123 layers, at least 124 layers, at least 125 layers, at least 126 layers, at least 127 layers, at least 128 layers, at least 129 layers, at least 130 layers, at least 131 layers, at least 132 layers, at least 133 layers, at least 134 layers, at least 135 layers, at least 136 layers, at least 137 layers, at least 138 layers, at least 139 layers, at least 140 layers, at least 141 layers, at least 142 layers, at least 143 layers, at least 144 layers, at least 145 layers, at least 146 layers, at least 147 layers, at least 148 layers, at least 149 layers, at least 150 layers, at least 151 layers, at least 152 layers, at least 153 layers, at least 154 layers, at least 155 layers, at least 156 layers, at least 157 layers, at least 158 layers, at least 159 layers, at least 160 layers, at least 161 layers, at least 162 layers, at least 163 layers, at least 164 layers, at least 165 layers, at least 166 layers, at least 167 layers, at least 168 layers, at least 169 layers, at least 170 layers, at least 171 layers, at least 172 layers, at least 173 layers, at least 174 layers, at least 175 layers, at least 176 layers, at least 177 layers, at least 178 layers, at least 179 layers, at least 180 layers, at least 181 layers, at least 182 layers, at least 183 layers, at least 184 layers, at least 185 layers, at least 186 layers, at least 187 layers, at least 188 layers, at least 189 layers, at least 190 layers, at least 191 layers, at least 192 layers, at least 193 layers, at least 194 layers, at least 195 layers, at least 196 layers, at least 197 layers, at least 198 layers, at least 199 layers and at least 200 layers.

According to one embodiment, the reflective portion is arranged on a substrate. This substrate may comprise or consist of Si, SiO₂ and/or SiC. The substrate may also be made of glass.

According to an embodiment of the invention, the daytime radiative cooling device further comprises an emitting portion comprising at least one layer C consisting of a material C selected from among Nb₂O₅, SiO₂, SiC, TiO₂, Ta₂O₅ and Al₂O₃, the material C being different from the material(s) A and the material(s) B of the reflective portion, the reflective portion being arranged on the emitting portion. The emitting portion emits a radiation in the wavelengths from 7,500 to 13,300 nm. Thus, the presence of this emitting portion allows increasing the emission performances for the wavelengths of the ATW of the daytime radiative cooling device according to the invention. Furthermore, the materials used in this emitting portion are advantageously inexpensive, are stable over time and are not or barely sensitive to photo-destruction. The reflective and emitting portions are superposed on top of one another, and not side-by-side. This allows combining their effect on the solar radiation and improving the refrigeration performances. During use of the device of the invention, the reflective portion forms the upper portion. It is arranged facing the solar radiation and is therefore above the emitting portion, the latter thus forming the lower portion.

The material C corresponds to a material having an average extinction coefficient value k for the wavelengths of the ATW higher than 0.40 (cf. FIGS. 10, 11, 12b, 13b, 14b and 15b). The Inventors have discovered that, unexpectedly, the Nb₂O₅ material has such a property, and therefore it could also be used in the emitting portion of the daytime radiative device of the invention.

The emissivity performances for wavelengths in the ATW of the daytime radiative device are obtained by the specific combination of the material C of the emitting portion and of the material(s) B of the reflective portion. Hence, the layers B serve both in the reflective portion in the context of the reflection performances for the wavelengths from 260 nm to 2,500 nm, and in the emitting portion in the context of the emissivity performances for wavelengths in the ATW. Preferably, one of the materials B and C is SiO₂.

The daytime radiative cooling device may have layers having one of the 64 compositions listed in the following table:

TABLE 2

| | REFLECTIVE PORTION | | | | | EMITTING PORTION | | | | | |
|---|---|---|---|---|---|---|---|---|---|---|---|
| | Layers A | | | Layers B | | Layer(s) C | | | | | |
| Comp. | Nb₂O₅ | TiO₂ | Ta₂O₅ | SiO₂ | Al₂O₃ | SiC | TiO₂ | Ta₂O₅ | SiO₂ | Al₂O₃ | Nb₂O₅ |
| 1 | + | | | + | | + | | | | | |
| 2 | | + | | + | | + | | | | | |
| 3 | | | + | + | | + | | | | | |
| 4 | + | + | | + | | + | | | | | |
| 5 | + | | + | + | | + | | | | | |
| 6 | | + | + | + | | + | | | | | |
| 7 | + | + | + | + | | + | | | | | |
| 8 | + | | | | + | + | | | | | |
| 9 | | + | | | + | + | | | | | |
| 10 | | | + | | + | + | | | | | |
| 11 | + | + | | | + | + | | | | | |
| 12 | + | | + | | + | + | | | | | |
| 13 | | + | + | | + | + | | | | | |
| 14 | + | + | + | | + | + | | | | | |
| 15 | + | | | + | + | + | | | | | |
| 16 | | + | | + | + | + | | | | | |
| 17 | | | + | + | + | + | | | | | |
| 18 | + | + | | + | + | + | | | | | |
| 19 | + | | + | + | + | + | | | | | |
| 20 | | + | + | + | + | + | | | | | |
| 21 | + | + | + | + | + | + | | | | | |
| 22 | + | | | + | | | + | | | | |
| 23 | | | + | + | | | + | | | | |
| 24 | + | | + | + | | | + | | | | |
| 25 | + | | | | + | | + | | | | |
| 26 | | | + | | + | | + | | | | |
| 27 | + | | + | | + | | + | | | | |
| 28 | + | | | | + | | + | | | | |
| 29 | + | | | + | + | | + | | | | |
| 30 | | | + | + | + | | + | | | | |
| 31 | + | | + | + | + | | + | | | | |
| 32 | + | | | + | | | | + | | | |
| 33 | | + | | + | | | | + | | | |
| 34 | + | + | | + | | | | + | | | |
| 35 | + | | | + | | | | + | | | |
| 36 | + | | | | + | | | + | | | |
| 37 | | + | | | + | | | + | | | |
| 38 | + | + | | | + | | | + | | | |
| 39 | + | | | + | + | | | + | | | |
| 40 | | + | | + | + | | | + | | | |
| 41 | + | + | | + | + | | | + | | | |
| 42 | + | | | | + | | | | + | | |
| 43 | | + | | | + | | | | + | | |
| 44 | | | + | | + | | | | + | | |
| 45 | + | + | | | + | | | | + | | |
| 46 | + | | + | | + | | | | + | | |
| 47 | | + | + | | + | | | | + | | |
| 48 | + | + | + | | + | | | | + | | |
| 49 | + | | | + | | | | | | + | |
| 50 | | + | | + | | | | | | + | |
| 51 | | | + | + | | | | | | + | |
| 52 | + | + | | + | | | | | | + | |
| 53 | + | | + | + | | | | | | + | |
| 54 | | + | + | + | | | | | | + | |
| 55 | + | + | + | + | | | | | | + | |
| 56 | | + | | + | | | | | | | + |
| 57 | | | + | + | | | | | | | + |
| 58 | | + | + | + | | | | | | | + |
| 59 | | + | | | + | | | | | | + |
| 60 | | | + | | + | | | | | | + |
| 61 | | + | + | | + | | | | | | + |
| 62 | | + | | + | + | | | | | | + |
| 63 | | | + | + | + | | | | | | + |
| 64 | | + | + | + | + | | | | | | + |

According to one embodiment, the reflective portion is arranged on a substrate as defined hereinabove.

One or more layer(s) B may also be present in the emitting portion, to contribute to the emissivity performances for wavelengths in the ATW.

According to an embodiment of the invention, the emitting portion comprises at least one superposition of at least one layer C and of at least one layer B, the selected material B and material C being different. Preferably, one of the materials B and C of the emitting portion is SiO₂.

In this embodiment, the reflective portion may be made up of only two layers, a layer B and a layer C.

According to one embodiment, the layer(s) B of the emitting portion and the layers B of the reflective portion consist of the same material B.

The emitting portion may comprise an even or odd number of superposed layers.

According to an embodiment of the invention, all of the layers C have a total thickness of at least 1 μm. An increase in the total thickness of all of the layers C allows improving the emissivity performances for wavelengths in the ATW of the emitting portion. Thus, it is in particular included within the scope of the invention at least 1 μm, at least 1.1 μm, at least 1.2 μm, at least 1.3 μm, at least 1.4 μm, at least 1.5 μm, at least 1.6 μm, at least 1, 7 μm, at least 1.8 μm, at least 1.9 μm, at least 2 μm, at least 2.1 μm, at least 2.2 μm, at least 2.3 μm, at least 2.4 μm, at least 2.5 μm, at least 2.6 μm, at least 2.7 μm, at least 2.8 μm, at least 2.9 μm, at least 3 μm, at least 3.1 μm, at least 3.2 μm, at least 3.3 μm, at least 3.4 μm, at least 3.5 μm, at least 3.6 μm, at least 3.7 μm, at least 3.8 μm, at least 3.9 μm, at least 4 μm, at least 4.1 μm, at least 4.2 μm, at least 4.3 μm, at least 4.4 μm, at least 4.5 μm, at least 4, 6 μm, at least 4.7 μm, at least 4.8 μm, at least 4.9 μm, at least 5 μm, at least 5.1 μm, at least 5.2 μm, at least 5.3 μm, at least 5.4 μm, at least 5.5 μm, at least 5.6 μm, at least 5.7 μm, at least 5.8 μm, at least 5.9 μm, at least 6 μm, at least 6.1 μm, at least 6.2 μm, at least 6.3 μm, at least 6.4 μm, at least 6.5 μm, at least 6.6 μm, at least 6.7 μm, at least 6.8 μm, at least 6.9 μm, at least 7 μm, at least 7.1 μm, at least 7.2 μm, at least 7.3 μm, at least 7.4 μm, at least 7, 5 μm, at least 7.6 μm, at least 7.7 μm, at least 7.8 μm, at least 7.9 μm, at least 8 μm, at least 8.1 μm, at least 8.2 μm, at least 8.3 μm, at least 8.4 μm, at least 8.5 μm, at least 8.6 μm, at least 8.7 μm, at least 8.8 μm, at least 8.9 μm, at least 9 μm, at least 9.1 μm, at least 9.2 μm, at least 9.3 μm, at least 9.4 μm, at least 9.5 μm, at least 9.6 μm, at least 9.7 μm, at least 9.8 μm, at least 9.9 μm or at least 10 μm.

According to an embodiment of the invention, the structure of the reflective portion is determined by automated means implementing the following steps:
a) providing a base reflection structure, said structure having a thickness and consisting of at least one layer A and/or of at least one layer B, said layer A consisting of a material A selected from among Nb₂O₅, TiO₂ and Ta₂O₅ and said layer B consisting of a material B selected from among SiO₂ and Al₂O₃,
b) determining an improved reflection structure by means of the following sub-steps:
i. selecting a wavelength whose reflection is to be improved, said wavelength being selected from a range of reflection wavelengths from 260 nm to 2,500 nm,
ii. selecting a material to be inserted according to the following criteria:
said material to be inserted is selected from among those of the material B if the base reflection structure consists of a layer A,
said material to be inserted is selected from among those of the material A if the base reflection structure consists of a layer B,
said material to be inserted is selected from among those of the material A or from those of the material B in all other cases,
iii. determining the number of new layers to be inserted into the base reflection structure and their position within the base reflection structure, a new layer consisting of said material to be inserted and inserted according to the thickness of the base reflection structure,
said number and said position being determined according to the selected wavelength and the selected material to be inserted,
iv. determining the thickness of the or each new layer and obtaining an improved reflection structure in which the new layer(s) is/are incorporated,
c) determining a reflection performance value χ_{R} of the improved structure using the following formula

$${χ}_{R} = \frac{1}{\sqrt{N}} \sqrt{{\sum }_{i = 1}^{N} \frac{{( {R}_{SRA} ( {λ}_{i} ) - {R}_{F M} ( {λ}_{i} ) )}^{2}}{{tol}^{2}}} \qquad [ Math 2 ]$$

where
λᵢ is a wavelength (in nanometres) in the range of reflection wavelengths,
N is the number of spectral wavelengths in the range of reflection wavelengths,
R_{SRA}(λᵢ) is the coefficient of reflection obtained for the improved reflection structure at the spectral wavelength λᵢ,
R_{FM}(λᵢ) is the coefficient of reflection to be reached at the wavelength λᵢ, and tol has a value of 0.1,
d) if χ_{R} has a value lower than or equal to a reference value χ_{Rref}, determining the improved reflection structure as corresponding to the reflective portion of the daytime radiative device; or
if χ_{R} has a value higher than the reference value χ_{Rref}, repeating steps b) to d) while selecting the base reflection structure as being the improved reflection structure determined in step b).

Thus, the Inventors have also succeeded in developing a new method for determining the structure of the reflective portion of a daytime radiative device according to the invention. This method is based on simulations of repeated insertions of new layers in a basic structure and of determining the theoretical performances of the obtained structures until reaching the structure featuring the desired performances. The position and the thickness of each new layer are determined so as to improve the performances of the structure. Hence, this method advantageously allows determining a wide variety of structures for the reflective portion without having to manufacture each prototype, which considerably reduces the development costs of a daytime radiative cooling device. For the rest of the description, the term “performance” should be understood as corresponding to a “theoretical performance”. Nevertheless, the methods for calculating the theoretical performances mentioned hereinafter have been tested for a long time by the state of the art, so that the obtained theoretical performances correspond to the performances actually obtained of the manufactured device.

By “automated means”, it should be understood in the invention one or more data processing member(s), for example one or more computer(s), which carry out the method intended to achieve the mentioned purpose. Next, “means” or “automated means” will refer to any type of automated means such as those mentioned before, which allow carrying out process steps in an automatic and digital manner, by means of a computing power supplied by a few processors, or, also possibly, by means of telecommunications networks. These means include or encompass the database services intended to record or obtain any type of data necessary for carrying out the described steps, such as calculated values, the position of the layers, etc. Hence, the steps described hereinafter may be written in the form of one or more computer program(s), which may be executed automatically at the choice of a user of the invention.

### Step a

This step defines the base reflection structure in terms of composition and thickness.

The composition of the base reflection structure may be monolayer or multilayer. In particular, it may already have an alternation of layers A and B, or simply only one of these layers.

Advantageously, the base reflection structure may have any thickness. Indeed, the thickness of the layer(s) making it up will be adapted during step b) by insertion of one or more layer(s), or during the next iteration(s). Preferably, the base reflection structure may have a thickness of at least 100 nm, more preferably at least 300 nm, advantageously at least 500 nm.

### Step b

This step allows obtaining an improved reflection structure having a better reflection of the waves of the range of reflection wavelengths than the base reflection structure, by improving the reflection of one of these wavelengths. It results from this operation that the reflection of the close wavelengths is also improved.

According to a particular embodiment of the invention, to carry out sub-step i. of step b), the automated means implement the following sub-steps:
determining the coefficients of reflection R_{SRB}(λ) of the base reflection structure for each of the wavelengths of the range of reflection wavelengths, and
selecting the or one of the wavelengths having the coefficient of reflection R_{SRB} the furthest from R_{FM}(λᵢ).

According to the invention, the coefficient of reflection corresponds to the intensity coefficient of reflection R and these terms will be used as synonyms and interchangeably. The coefficient of reflection of a wavelength wave represents the fraction of the wave which is reflected by the considered system (herein the base reflection structure) and has a value comprised from 0 to 1, in particular between 0 and 1. A value of 0 indicates that no reflection of the wave is obtained by the system and a value of 1 indicates that the entire wave is reflected by the system. Thus, in this embodiment, the selected wavelength corresponds to that one amongst the wavelengths of the reflection range for which the reflection by the base reflection structure is the lowest.

The coefficient of reflection of a wave by a given system is obtained by different methods known to a person skilled in the art. In particular, its value may be obtained according to the transfer matrix method, described, for example, in the document by Pochi Yeh, Optical Waves in Layered Media, Wiley, 2005. In brief, the principle of this method is to associate with each material layer (corresponding to a blade of material separated from two other blades of material by two dioptres) a specific 2×2 matrix. Thus, this method allows determining the characteristics related to the propagation of a wave in a system composed of several dioptres by simple multiplication of the specific matrices.

In particular, in order to determine the value of the intensity coefficient R, a system formed by air, the base structure and a substrate as defined hereinabove, is considered.

The pairs of materials A and B from that of the base structure are sorted in the table hereinbelow according to the obtained reflection performances (from the best to the worst):

TABLE 3

| | |
|---|---|
| | Material to |
| Base structure | be inserted |

| | | |
|---|---|---|
| LAYER A | TiO₂ | SiO₂ |
| | Nb₂O₅ | SiO₂ |
| | TiO₂ | Al₂O₃ |
| | Nb₂O₅ | Al₂O₃ |
| | Ta₂O₅ | SiO₂ |
| | Ta₂O₅ | Al₂O₃ |
| LAYER B | SiO₂ | TiO₂ |
| | SiO₂ | Nb₂O₅ |
| | Al₂O₃ | TiO₂ |
| | Al₂O₃ | Nb₂O₅ |
| | SiO₂ | Ta₂O₅ |
| | Al₂O₃ | Ta₂O₅ |

According to a particular embodiment of the invention, to carry out sub-step ii. of step b) when the base reflection structure consists of a layer A, the selected material to be inserted is SiO₂. Indeed, regardless of the material A making up the layer of the base structure, SiO₂ corresponds to the material B having a refractive index of the wavelengths from 260 to 2,500 nm having the highest contrast with the refractive index of these wavelengths of the material A of the layer A. By higher contrast, it should be understood in the invention the highest difference.

According to a particular embodiment of the invention, to carry out sub-step ii. of step b) when the base reflection structure consists of a layer b, the selected material to be inserted is TiO₂. Indeed, regardless of the material B making up the layer of the base structure, TiO₂ corresponds to the material A having a refractive index of the wavelengths from 260 to 2,500 nm having the highest contrast with the refractive index of these wavelengths of the material B of the layer B.

According to a particular embodiment of the invention, to carry out sub-step ii. of step b) in all other cases, the material to be inserted corresponds to that of the at least one of the layers A or to that of the at least one of the layers B. Alternatively, the material to be inserted is selected from among those of the material A and is different from that of the layer A or of those of the layers A or is selected from among those of the material B and is different from that of the layer B or those of the layers B.

According to a particular embodiment of the invention, to carry out sub-step iii. of step b), the automated means implement the following sub-steps:
determining the derivative of the coefficient of reflection R_{SRB}(λ) of the base reflection structure for the selected wavelength according to the thickness (p) of said base reflection structure,
determining the number of new layers to be inserted into the base reflection structure as corresponding to the number of times the derivative is cancelled by passing from a negative extremum to a positive extremum, and
determining the position of the new layer(s) to be inserted into the base reflection structure as corresponding to each of the values of p for which the derivative is cancelled by passing from a negative extremum to a positive extremum.

Alternatively, to carry out sub-step iii. of step b), the automated means implement the following sub-steps:
determining the derivative and the second derivative of the coefficient of reflection R_{SRB}(λ) of the base reflection structure for the selected wavelength according to the thickness (p) of said base reflection structure,
determining the number of new layers to be inserted into the base reflection structure as corresponding to the number of times the derivative is equal to 0 with a negative second derivative, and
determining the position of the new layer(s) to be inserted into the base reflection structure as corresponding to each of the values of p for which the derivative is equal to 0 with a negative second derivative.

The first one of the sub-steps of determination of the derivative of the coefficient of reflection R_{SRB}(λ) may be carried out based on a method known from the state of the art referred to as the “Needle” method (“Needle”), described in particular in the document by A. V. Tikhonravov, Vestn. Mosk. Univ. Fiz. Astronomiya 23, 91-93, 1982. In brief, this method simulates the presence of a new layer having an infinite thickness (smaller than 1 nm) at a given nanometric position of the thickness of the base reflection structure. Based on this simulation, the derivative and the second derivative of the value of the coefficient of reflection of the base reflection structure for the selected wavelength are obtained at the considered value of the thickness of the base reflection structure. To obtain all of the derivative and second derivative values, the layer with an infinitesimal thickness is moved virtually at all nanometric positions of the thickness of a considered structure. The Inventors have been able to establish that this virtual movement could be carried out based on the transfer matrix method.

Indeed, using the formalism of P. Yeh, (mentioned hereinabove), the amplitude of an incoming planar wave

$$\begin{matrix}[ Math 4 ] & \\ ( \begin{matrix}{A}_{e} \\ {B}_{e}\end{matrix} ) & \end{matrix}$$

can be related to the outcoming amplitude

$$\begin{matrix}[ Math 5 ] & \\ ( \begin{matrix}{A}_{s} \\ {B}_{s}\end{matrix} ) & \end{matrix}$$

of an optical system consisting of N stacked layers comprised between two semi-infinite media, the input e and output s media

$$\begin{matrix}[ Math 6 ] & \\ ( \begin{matrix}{A}_{e} \\ {B}_{e}\end{matrix} ) = {D}_{e}^{- 1} [ {\prod }_{i = 1}^{N} {D}_{i} {P}_{i} {D}_{i}^{- 1} ] {D}_{s} \cdot ( \begin{matrix}{A}_{s} \\ {B}_{s}\end{matrix} ) = ( \begin{matrix}{m}_{11} & {m}_{12} \\ {m}_{21} & {m}_{22}\end{matrix} ) \cdot ( \begin{matrix}{A}_{s} \\ {B}_{s}\end{matrix} ) & ( 1 )\end{matrix}$$

The matrix

$$\begin{matrix}[ Math 7 ] & \\ ( \begin{matrix}{m}_{11} & {m}_{12} \\ {m}_{21} & {m}_{22}\end{matrix} ) & \end{matrix}$$

is the resultant matrix resulting from the product of the dynamic 2*2 matrices D_{I}, D_{I}⁻¹ and of the phase P_{I} of each considered layer in the stack.

By definition, the coefficient of reflection r and of transmission t in amplitude are

$$\begin{matrix}[ Math 8 ] & \\ r = ( \frac{{B}_{e}}{{A}_{e}} ) & ( 2 )\end{matrix}$$

$$and$$

$$\begin{matrix}[ Math 9 ] & \\ t = ( \frac{{A}_{s}}{{A}_{e}} ) & \end{matrix}$$

Hence, we have

$$\begin{matrix}[ Math 10 ] & \\ r = ( \frac{{m}_{21}}{{m}_{11}} ) & ( 3 )\end{matrix}$$

$$and$$

$$\begin{matrix}[ Math 11 ] & \\ t = ( \frac{1}{{m}_{11}} ) & \end{matrix}$$

And the coefficients of reflection r and transmission t in intensity are

$$\begin{matrix}[ Math 12 ] & \\ R = {\vert r \vert}^{2} = {\vert ( \frac{{m}_{21}}{{m}_{11}} ) \vert}^{2} & ( 4 )\end{matrix}$$

$$and$$

$$\begin{matrix}[ Math 13 ] & \\ T = {\vert t \vert}^{2} = \frac{ℛ ( {κ}_{s} )}{ℛ ( {κ}_{e} )} {\vert ( \frac{1}{{m}_{11}} ) \vert}^{2} & \end{matrix}$$

The intensity absorption coefficient is given by the following relationship

$$\begin{matrix}[ Math 14 ] & \\ A = 1 - R - T & ( 5 )\end{matrix}$$

For one stack, the relationship between the amplitudes in the medium i is given by

$$\begin{matrix}[ Math 15 ] & \\ ( \begin{matrix}{A}_{i} \\ {B}_{i}\end{matrix} ) = ( \begin{matrix}{m}_{11} & {m}_{12} \\ {m}_{21} & {m}_{22}\end{matrix} ) \cdot ( \begin{matrix}{A}_{s} \\ {B}_{s}\end{matrix} ) & ( 6 )\end{matrix}$$

The variation of the coefficients r and t as a function of a parameter p (could be the thickness, the angle, the wavelength) is given by

$$\begin{matrix}[ Math 16 ] & \\ \frac{dr}{dp} = \frac{1}{{A}_{i}} \frac{{dB}_{i}}{dp} - \frac{{B}_{i}}{{A}_{i}^{2}} \cdot \frac{{dA}_{i}}{dp} = \frac{1}{{m}_{11}} \frac{{dm}_{21}}{dp} - \frac{{m}_{21}}{{m}_{11}^{2}} \cdot \frac{{dm}_{11}}{dp} & ( 7 )\end{matrix}$$

$$\begin{matrix}[ Math 17 ] & \\ \frac{dt}{dp} = \frac{1}{{A}_{i}} \frac{{dA}_{s}}{dp} - \frac{{A}_{s}}{{A}_{i}^{2}} \cdot \frac{{dA}_{i}}{dp} = \frac{1}{{m}_{11}^{2}} \cdot \frac{{dm}_{11}}{dp} & ( 8 )\end{matrix}$$

The variation induced by the addition of an infinitely fine matrix of thickness d Z in the stack may be written

$$\begin{matrix}[ Math 18 ] & \\ & ( 9 )\end{matrix}$$

$$( \begin{matrix}\frac{{dA}_{i}}{dz} \\ \frac{{dB}_{i}}{dz}\end{matrix} ) = ( \begin{matrix}\frac{{dm}_{11}}{dz} & \frac{{dm}_{12}}{dz} \\ \frac{{dm}_{21}}{dz} & \frac{{dm}_{22}}{dz}\end{matrix} ) \cdot ( \begin{matrix}{A}_{s} \\ {B}_{s}\end{matrix} ) = {D}_{e}^{- 1} … {D}_{i} \frac{{dP}_{i}}{dz} {D}_{i}^{- 1} … {D}_{s} \cdot ( \begin{matrix}{A}_{s} \\ {B}_{s}\end{matrix} )$$

The expressions of

$$\begin{matrix}[ Math 19 ] & \\ \frac{dR}{dz} , & \end{matrix}$$

$$\begin{matrix}[ Math 20 ] & \\ \frac{dT}{dz} & \end{matrix}$$

$$and$$

$$\begin{matrix}[ Math 21 ] & \\ \frac{dA}{dz} & \end{matrix}$$

become

$$\begin{matrix}[ Math 22 ] & \\ \frac{dR}{dz} = 2 \cdot {r}^{*} \cdot \frac{dr}{dz} & ( 10 )\end{matrix}$$

$$\begin{matrix}[ Math 23 ] & \\ \frac{dT}{dz} = 2 \cdot \frac{ℛ ( {κ}_{s} )}{ℛ ( {κ}_{e} )} \cdot {t}^{*} \cdot \frac{dt}{dz} & ( 11 )\end{matrix}$$

$$\begin{matrix}[ Math 24 ] & \\ \frac{dA}{dz} = - 2 \cdot {r}^{*} \cdot \frac{dr}{dz} - 2 \cdot \frac{ℛ ( {κ}_{s} )}{ℛ ( {κ}_{e} )} \cdot {t}^{*} \cdot \frac{dt}{dz} & ( 12 )\end{matrix}$$

The function χₘ to be minimised to optimise a quantity R(i), T(i) or A(i) is a function of the following figure of merit Fₘ

$$\begin{matrix}[ Math 25 ] & \\ {χ}_{m} = \frac{1}{\sqrt{N}} \sqrt{\frac{{\sum }_{t}^{N} {( X ( i ) - {F}_{m} ( i ) )}^{2}}{{tol}^{2}}} & ( 13 )\end{matrix}$$

The derivative of this equation with respect to z gives

$$\begin{matrix}[ Math 26 ] & \\ [ 1 ] \frac{{d}_{{χ}_{m}}}{dz} = \frac{1}{2 N} {( \frac{{\sum }_{t}^{N} {( X ( i ) - {F}_{m} ( i ) )}^{2}}{{tol}^{2}} )}^{- \frac{1}{2}} \cdot \frac{dx ( i )}{dz} & ( 14 )\end{matrix}$$

Hence, it results that the derivative of the function χₘ is a function of the derivative of a spectroscopic quantity R, T or A. Hence, searching for the extrema of the figure χₘ amounts to searching for the extrema of the spectroscopic function R, T or A.

Thus, in summary, to establish

$$\frac{dR}{dz} , \qquad [ Math 27 ]$$

[Math 28] should be

$$\frac{dR}{dz} = 2 \cdot {r}^{*} \cdot \frac{dr}{dz} \qquad ( 15 )$$

with

$$[ Math 29 ]$$

$$\frac{dr}{dz} = \frac{1}{{m}_{11}} \frac{{dm}_{21}}{dz} - \frac{{m}_{21}}{{m}_{11}^{2}} \cdot \frac{{dm}_{11}}{dz} \qquad ( 16 )$$

and the matrix elements derived from e are obtained by

$$[ Math 30 ]$$

$$( \begin{matrix}\frac{{dm}_{11}}{dz} & \frac{{dm}_{12}}{dz} \\ \frac{{dm}_{21}}{dz} & \frac{{dm}_{22}}{dz}\end{matrix} ) = {D}_{e}^{- 1} … {D}_{i} \frac{{dP}_{i}}{dz} {{D}_{i}}^{- 1} … {D}_{s} \qquad ( 17 )$$

Then, the following expressions are obtained

$$[ Math 31 ]$$

$$\frac{dR}{dz} = 2 \cdot {r}^{*} \cdot \frac{1}{{m}_{11}} \frac{{dm}_{21}}{dz} - \frac{{m}_{21}}{{m}_{11}^{2}} \cdot \frac{{dm}_{11}}{dz} \qquad ( 18 )$$

$$[ Math 32 ]$$

$$\frac{dT}{dz} = 2 \cdot \frac{ℛ ( {κ}_{s} )}{ℛ ( {κ}_{e} )} \cdot {t}^{*} \cdot - \frac{1}{{m}_{11}^{2}} \cdot \frac{{dm}_{11}}{dz} \qquad ( 19 )$$

$$[ Math 33 ]$$

$$\frac{dA}{dz} = - 2 \cdot {r}^{*} \cdot \frac{1}{{m}_{11}} \frac{{dm}_{21}}{dz} - \frac{{m}_{21}}{{m}_{11}^{2}} \cdot \frac{{dm}_{11}}{dz} - 2 \cdot \frac{ℛ ( {κ}_{s} )}{ℛ ( {κ}_{e} )} \cdot {t}^{*} \cdot - \frac{1}{{m}_{11}^{2}} \cdot \frac{{dm}_{11}}{dz} \qquad ( 20 )$$

To establish a spectrum of

$$\frac{dR}{dz} ( z ) , \qquad [ Math 34 ]$$

$$\frac{dT}{dz} ( z ) \qquad [ Math 35 ]$$

$$or$$

$$\frac{dA}{dz} ( z ) \qquad [ Math 36 ]$$

according to the thickness, these calculations should be repeated for an infinitesimal variation of the thickness dz varying from 0 to the considered total thickness dₜₒₜ.

According to one embodiment, to carry out sub-step iv. of step b), the automated means implement the following steps:
1. predetermining the thickness of the at least one new layer by means of a genetic algorithm, preferably coupled to a simplex algorithm, applied to the new layer(s),
2. obtaining a pre-improved reflection structure in which the new layer(s) is/are incorporated,
3. adjusting the thickness of the new layer(s) by means of a genetic algorithm, preferably coupled to a simplex algorithm, applied to the entire pre-improved reflection structure, and
4. obtaining an improved emissivity structure in which the new layer(s) is/are incorporated, the thickness of which is thus adjusted.

In particular, following step 2 and/or step 3. The automated means implement the following sub-steps:
merging the contiguous layers made of the same material, and/or
eliminating the layer(s) having a value lower than z_{ref}.

The purpose of the elimination sub-step is to not preserve the layers that would have a small thickness, more difficult to deposit and which would generate higher production costs. In particular, z_{ref} has a value of 4 nm, of 3 nm, of 2 nm or of 1 nm.

Genetic algorithms are widely known from the state of the art. The interest of these algorithms is that they allow obtaining various solutions to the same problem, and therefore in the context of the invention, obtaining different reflection structures having different thicknesses, but featuring the desired refrigeration performance.

In brief, genetic algorithms are intended to simulate the natural evolution process according to the Darwinian model in a given environment. They use a vocabulary similar to that of natural genetics. Thus, we will talk about individuals in a population. The principles of selection, crossing, mutation are based on natural processes of the same name. For a given optimisation problem, an evolutionary algorithm optimises a function so-called objective function (here χ_{R} and/or χ_{A}) on a search space including the objective function and a set of individuals of the state space. For this purpose, a population of individuals evolves according to an artificial Darwinism (reproduction, mutation, natural selection) based on the minimisation (reaching the lowest value) of the objective function determined based on these same individuals. The objective function may be determined for each individual or by a combination of individuals. Operators applied to the population allow creating new individuals (crossing and mutation) and selecting the individuals of the population who will survive (selection and replacement). The selection is intended to promote the best elements of the population for the considered criterion (with the best refrigeration performances), the crossing and the mutation ensure the exploration of the state space, i.e. in this case exploiting as many thickness values as possible.

In particular, to carry out the genetic algorithm of step 1. of sub-step iv., the automated means implement the following sub-steps:
aa) obtaining a populationₙ consisting of at least 10 parent individuals, each parent individual corresponding to a reflection structure comprising the layer(s) of the base reflection structure as well as one or more new layer(s) according to the result obtained in sub-step iii. of step b), said new layer(s) having a stochastically generated thickness, said new layer(s) being inserted into each individual at the positions determined in sub-step iii. of step b),
bb) determining the reflection performance value χ_{R} of each parent individual,
cc) obtaining the predetermined value of the thickness of the or each new layer to be inserted as corresponding to that of the new layer(s) of the best parent individual (i.e. the parent individual having the lowest value χ_{R}) if its value χ_{R} is lower than χ_{Rref}, or
   continuing to step dd),
dd) obtaining child individuals by crossings of the parent individuals with one another, said crossing of the parent individuals being carried out while considering for each parent individual that the thickness of the individual one or of each individual one of the new individual layers (without the layers of the base structure), so that each child individual comprises the same number of layers at the same position as the parent individuals with a thickness value of the or each new layer resulting from crossing of two parent individuals, the number of child individuals corresponding to the number of parent individuals,
and mutations of the child individuals, said mutation of the child individuals being carried out by mutation of the thickness value of the individual one or of each individual one of the new individual layers (without the layers of the base structure), all of the child individuals thus obtained after mutation being called offspring, ee) determining the reflection performance value χ_{R} of each individual child of the offspring,
ff) conclusion:
obtaining the predetermined value of the thickness of the or each new layer to be inserted as corresponding to that of the new or those of the new layers of the best child individual of the offspring (i.e. having the lowest value χ_{R}) if its value χ_{R} is lower than χ_{Rref} or
repeating the sub-steps dd) to ff) while considering a populationₙ₊₁ consisting of parent individuals corresponding to the child individuals of the obtained present offspring (populationₙ). When said best child individual of the present offspring has a value χ_{R} higher than the value χ_{R} of the best parent individual (populationₙ₋₁), said repetition of the sub-steps dd) to ff) may be carried out while considering the parent individuals of the populationₙ₋₁ as parent individuals.

In particular, during step aa), the stochastic generation generates layers having a thickness of 1 nm to 1,750 nm.

In particular, during step aa), if the number y of layers of each parent individual is greater than or equal to 10, then at least y+1 parent individuals are generated. This aspect is necessary when a simplex algorithm is coupled to the genetic algorithm. Indeed, a number of individuals greater than the number of layers is necessary to carry out the simplex algorithm.

In particular, for the calculation of the performance value χ_{R}, a system formed by air, the considered individual and a substrate as defined before, is considered.

As individual crossing operations, the example of barycentric, random barycentric, multi-point and sbx (“simulated binary crossover”) crossings will be given. Preferably, each crossing operation is an sbx crossing. More preferably, said sbx crossing is carried out according to the probability of application of a crossing to a parent individual pc=0.6. The different mathematical operations relating to each crossing type are part of the general knowledge of a person skilled in the art. In particular, for the sbx-type crossing, reference will be made to the document by K. Deb and R. B. Agrawal, Academic, 1995, pp. 115-148. For the various types of barycentric crossing, reference will be made to the document by Mourad Sefrioui, PhD thesis, Pierre et Marie Curie University, April 1998.

As individual mutation operations, the example of Gaussian and non-uniform mutations will be given. Preferably, each mutation operation is a non-uniform mutation. In particular, a non-uniform mutation controlled by the parameter b=1 (exploratory) or b=25 (local search) and the probability of applying a mutation to a child individual is pₘ=0.005. The mathematical operations relating to each mutation type are part of the general knowledge of a person skilled in the art. In particular, for the non-uniform mutations, reference will be made to the document by R. Numico, A. Keller, and O. Atabek, Phys. Rev. A 52, 1298 (1995). As regards Gaussian mutations, reference will be made to the document by Z. Michalewicz, Springer (1999).

According to one embodiment, after at least 10,000, in particular at least 100,000, in particular at least 150,000 repetitions of steps dd) to ff), the following conclusions could be considered in step ff):
obtaining the predetermined value of the thickness of the or each new layer to be inserted as corresponding to that of the new layer(s) of the best child individual of the offspring. In this aspect of the invention, when said best child individual of the offspring has a value χ_{R} higher than the value χ_{R} of the best parent individual (populationₙ₋₁), it may be considered to obtain the predetermined value of the thickness of the or each new layer to be inserted as corresponding to that of the new layer(s) of said best parent individual; or
recovering the child individuals of the offspring and applying a simplex algorithm to this offspring. When the best individual child of the offspring (populationₙ) has a value χ_{R} higher than the value χ_{R} of the best parent individual (populationnₙ₋₁), it may be considered to recover the parent individuals from the populationnₙ₋₁ and apply a simplex algorithm to said parent individuals.

In this embodiment, a continuation of the method for determining the reflective portion despite the absence of reaching the performance value χ_{Rref} by the best child individual of the offspring is considered. Indeed, it is the repetition of steps b) to d) and the successive addition of new layers with an optimised thickness which allow achieving the desired performance value.

When obtaining the predetermined value of the thickness of the or each new layer to be inserted during step ff), the automated means implement the following sub-steps:
merging the contiguous layers consisting of the same material, and
eliminating the layer(s) having a value lower than z_{ref}.

In particular, to carry out the genetic algorithm of step 3. of sub-step iv. The automated means implement the same steps as those mentioned hereinabove for step 1., while considering:
that in step aa), each parent individual corresponds to a reflection structure comprising all of the layers of the pre-improved reflection structure, the thickness value of each layer of a parent individual being generated stochastically with a positive or negative variability of at most 50%, with the thickness value of the corresponding layer in the pre-improved emissivity structure,
that in step dd), the crossing of the parent individuals is carried out while considering all of the layers forming each parent individual, so that the thickness of all of the layers is variable between the parent individuals and the child individuals and
that in step dd), the mutation of the child individuals is carried out on all of the layers forming each child individual.

In particular, the positive or negative variability with the thickness value of the corresponding layer in the pre-improved structure is at most 40%, in particular at most 30%, for example at most 10%.

In the invention, the simplex algorithm corresponds to the Nelder-Mead method and these terms will be considered as synonyms and interchangeable. The Nelder-Mead method is very known from the state of the art. In particular, mention will be made of the document Numerical Recipes in Fortran 77 W. H. Press (chapter 10.4 pages 402-406).

In brief, the simplex algorithm is a heuristic numerical method which seeks to minimise a continuous function in a multi-dimensional space. In this case, the function to be minimised is the value χ_{R}. The term “simplex” refers to a generalisation of the triangle to any dimension. Thus, a simplex, or n-simplex, is the n-dimensional analog of the triangle forming a polytope with n+1 vertices (a triangle for 2 dimensions, a tetrahedron for 3 dimensions, etc.). Starting from such a simplex, the latter undergoes simple transformations throughout the iterations: it is deformed, moves in the space and is progressively reduced until its vertices approach a point where the function is locally minimal.

The simplex algorithm starts with the definition of a function f over a space with a dimension N. In the context of the present invention, the function f is the reflection performance value χ_{R}, and/or the absorption performance value χ_{A} as will be seen later on. In the N dimensions, N−1 dimensions correspond to the different layers of the individuals recovered for the simplex algorithm (children or parents) and last dimension represents the values χ_{R} of these individuals. In the present embodiment, the different layers of the individual correspond to those of the base reflection structure and the new one(s). The different layers may also correspond to those of the base emissivity structure and the new one(s) or those of the reflection portion and to those of the emissivity portion, in the context of the embodiment described later on. Afterwards, a non-degenerate simplex (polytope with N vertices, the vertices of which are not aligned) is defined in this space. Hence, the polytope comprises 1 vertex more than there are layers forming the structure of each recovered individual. Each vertex of the simplex is arranged at the coordinates of the thicknesses of the different layers forming the structure of a recovered individual. Through successive iterations, the process consists in determining the point of the simplex where the function is maximum in order to replace it by the reflection (i.e. the symmetrical) of this point with respect to the centre of gravity of the N−1 remaining points. If the value of the function at this new point is lower than all of the other values at the other points, the simplex is stretched in this direction. If the value of the function at this new point is comprised between the second and the first lower value, this value is kept and we start again. In all other cases, it is assumed that the local appearance of the function is a valley, and the simplex is contracted on itself. In the case where this contraction does not lead to a better point, the simplex is reduced by a homothety centred on the point of the simplex where the function is minimum.

### Step c

This step allows determining the reflection performance of the wavelengths of the reflection range by the improved reflection structure.

In particular, for the calculation of the performance value χ_{R}, a system formed by air, the improved structure and a substrate as defined hereinabove, is considered.

According to an embodiment of the invention, the value R_{FM}(λᵢ) is 1 for any wavelength of the range of reflection wavelengths.

### Step d

This step allows determining whether the reflection performances obtained for the improved reflection structure are satisfactory. In the case where these performances are not satisfactory, it is proceeded with a new iteration of steps b) to d) so as to improve these performances.

According to an embodiment of the invention, the value χ_{Rref} is equal to or lower than 1, preferably lower than or equal to 0.5, more preferably lower than or equal to 0.3, advantageously lower than or equal to 0.1. The lower the value χ_{Rref}, the greater the refrigeration performances will be. The refrigeration effect is obtained starting from a value χ_{Rref} of 1, in particular when the daytime radiative device comprises an emitting portion as defined hereinabove.

According to an embodiment of the invention, the structure of the emitting portion is determined by automated means implementing the following steps:
a) providing a base emissivity structure, said structure having a thickness and consisting of at least one layer C and/or of at least one layer B, said layer C consisting of a material C selected from among Nb₂O₅, SiO₂, SiC, TiO₂, Ta₂O₅ and Al₂O₃ and said layer B consisting of a material B selected from among SiO₂ and Al₂O₃, the material C being different from the material B and different from the material(s) A of the reflective portion, preferably one of the materials B and C is SiO₂,
b) determining an improved emissivity structure by means of the following sub-steps:
i. selecting a wavelength whose emissivity is to be improved, said wavelength being selected from a range of reflection wavelengths from 7,500 nm to 13,300 nm,
ii. selecting a material to be inserted according to the following criteria:
said material to be inserted is selected from among those of the material B if the base emissivity structure consists of a layer C,
said material to be inserted is selected from among those of the material C if the base emissivity structure consists of a layer B,
said material to be inserted is selected from among those of the material C or from those of the material B in all other cases,
iii. determining the number of new layers to be inserted into the base emission structure and their position within the base emissivity structure, a new layer consisting of said material to be inserted and inserted according to the thickness of the base emissivity structure,
said number and said position being determined according to the selected wavelength and the selected material to be inserted,
iv. determining the thickness of the or each new layer, and obtaining an improved emissivity structure in which the new layer(s) is/are incorporated,
c) determining an absorption performance value χ_{A} of the improved structure using the following formula

$${χ}_{A} = \frac{1}{\sqrt{N}} \sqrt{{\sum }_{i = 1}^{N} \frac{{( {A}_{SEA} ( {λ}_{i} ) - {A}_{F M} ( {λ}_{i} ) )}^{2}}{{tol}^{2}}} \qquad [ Math 37 ]$$

where
λᵢ is a wavelength (in nanometres) in the emission wavelength range,
N is the number of wavelengths in the emission wavelength range,
A_{SRA}(λᵢ) is the coefficient of absorption obtained for the improved structure at the spectral wavelength λᵢ,
A_{FM}(λᵢ) is the absorption value to be reached at the spectral wavelength Ai, and tol has a value of 0.1,
d) if χ_{A} has a value lower than or equal to a reference value χ_{Aref}, determining the improved emissivity structure as corresponding to the emitting portion of the daytime radiative device; or
if χ_{A} has a value higher than the reference value χ_{Aref}, repeating steps b) to d) while selecting the base emissivity structure as being the improved emissivity structure determined in step b).

In this aspect of the invention, the Inventors have succeeded in developing a method for determining the structure of the emitting portion according to a method equivalent to that one allowing determining the structure of the reflective portion described hereinabove, but taking into account the parameters specific to the emitting portion (materials to be used, wavelengths to be considered and performances to be tested). Herein again, this method advantageously allows determining a wide variety of structures for the emitting portion without having to manufacture each prototype, which considerably reduces the development costs of daytime radiative cooling devices.

### Step a

The composition of the base emissivity structure may be monolayer or multilayer. In particular, it may already have an alternation of layers C and B, or simply only one of these layers.

Advantageously, the base emissivity structure may have any thickness. Indeed, the thickness of the layer(s) making it up will be adapted during step b) by insertion of one or more layer(s), or during the next iteration(s). Preferably, the base emissivity structure may have a thickness of at least 1 nm, in particular from 1 to 50,000 nm, preferably of at least 100 nm, more preferably of at least 300 nm, advantageously at least 500 nm, for example at least 1,000 nm, in particular at least 5,000 nm.

### Step b

This step allows obtaining an improved emissivity structure having a better emission of the waves of the emission wavelength range than the base emissivity structure, by seeking to improve the absorption of one of these wavelengths.

Indeed, with the Kirchhoff approximation at thermal equilibrium: a (absorptivity)=ε (emissivity). The coefficient of absorption A is determined by means of the transfer matrices seen before and is a function of the absorptivity A=f(α) and therefore of the emissivity f(ε). Thus, the value of A is optimised in the method of the invention, since it is a directly calculated quantity, but it is the emissivity & which is indirectly optimised.

As was the case for reflection, by improving the emissivity of one of the wavelengths of the emission wavelength range, the emissivity of the close wavelengths is also improved.

According to a particular embodiment of the invention, to carry out sub-step i. of step b), the automated means implement the following sub-steps:
determining the coefficients of absorption A_{SEB}(λ) of the base emissivity structure for each of the wavelengths of the emission wavelength range, and
selecting the or one of the wavelengths having the coefficient of absorption A_{SEB} the furthest from 1.

In the invention, the coefficient of absorption corresponds to the intensity absorption coefficient A and these terms will be used as synonyms and interchangeably. The coefficient of absorption of a wavelength represents the fraction of the wave that is absorbed by the considered system (herein the base emissivity structure) and has a value comprised from 0 to 1, in particular between 0 and 1. A value of 0 indicates that no absorption of the wave is obtained by the system and a value of 1 indicates that the entire wave is absorbed by the system. Thus, in this embodiment, the selected wavelength corresponds to that one amongst the wavelengths of the emission range for which the absorption by the base emissivity structure is the lowest.

According to a particular embodiment of the invention, in order to carry out sub-step ii. of step b) in all the other cases, the material to be inserted corresponds to that of the or at least one of the layers C or to that of the or at least one of the layers B. Alternatively, the material to be inserted:
is selected from among those of the material C and is different from that of the layer C or of those of the layers C and is different from that of the layer B or of those of the layers B, or
is selected from among those of the material B and is different from that of the layer C or of those of the layers C and is different from that of the layer B or of those of the layers B.

Preferably, one of the materials B and C of the emitting portion is SiO₂.

According to a particular embodiment of the invention, to carry out sub-step
iii. of step b), the automated means implement the following sub-steps:
determining the derivative of the coefficient of absorption A_{SEB}(λ) of the base emissivity structure for the selected wavelength according to the thickness (p) of said base emissivity structure,
determining the number of new layers to be inserted into the base emissivity structure as corresponding to the number of times the derivative is cancelled by passing from a negative extremum to a positive extremum, and
determining the position of the new layer(s) to be inserted into the base emissivity structure as corresponding to each of the values of p for which the derivative is cancelled by passing from a negative extremum to a positive extremum.

The first one of the sub-steps for determining the derivative of the coefficient of reflection R_{SRB}(λ) may be carried out by the method derived from the above-described “Needle” method.

According to one embodiment, to carry out the sub-step iv. of step b), the automated means implement the following steps:
1. predetermining the thickness of the at least one new layer by means of a genetic algorithm, preferably coupled to a simplex algorithm, applied to the or each new layer,
2. obtaining a pre-improved emissivity structure by insertion of the new predetermined layer(s) into the base emissivity structure,
3. adjusting the thickness of the new layer(s) by means of a genetic algorithm, preferably coupled to a simplex algorithm, applied to the entire pre-improved emissivity structure, and
4. obtaining an improved emissivity structure in which the new layer(s) is/are incorporated, whose thickness is thus adjusted.

In particular, following step 2 and/or step 3, the automated means implement the following sub-steps:
merging the contiguous layers consisting of the same material, and/or
eliminating the layer(s) having a value lower than z_{ref}, in particular z_{ref} is 4 nm.

In particular, the genetic algorithm presented hereinabove for step 1. of sub-step iv. in the context of the reflective portion is applied mutatis mutandis in step 1. of sub-step iv. in the context of the emissivity portion, notwithstanding:
that in step aa), each parent individual corresponds to an emissivity structure comprising the layer(s) of the base emissivity structure as well as one or more new layer(s) according to the result obtained in sub-step iii. of step b), said new layer(s) having a stochastically generated thickness, said new layer(s) being inserted into each individual at the positions determined in sub-step iii. of step b),
that in steps bb) and ee), the absorption performance value χ_{A} it is determined for each individual (parent or child), said performance value being compared with the reference value χ_{Aref} during steps cc) and ff).

In particular, the stochastic generation in step a) generates layers having a thickness from 1 to 50,000 nm, in particular from 1 to 30,000 nm, for example from 1 to 10,000 nm.

In particular, the genetic algorithm presented hereinabove for step 3. of sub-step iv. in the context of the reflective portion applies mutatis mutandis in step 3. of sub-step iv. in the context of the emissivity portion, notwithstanding:
that in step aa), each parent individual corresponds to an emissivity structure comprising all of the layers of the pre-improved emissivity structure, the thickness value of each layer of a parent individual being generated stochastically with a positive or negative variability of at most 50%, with the thickness value of the corresponding layer in the pre-improved emissivity structure,
that in step dd), the crossing of the parent individuals is carried out while considering all of the layers forming each parent individual, so that the thickness of all of the layers is variable between the parent individuals and the child individuals and
that in step dd), the mutation of the child individuals is carried out on all of the layers forming each child individual, and
that in steps bb) and ee), the absorption performance value χ_{A} is determined for each individual (parent or child), said performance value being compared with the reference value χ_{Aref} during steps cc) and ff).

In particular, the positive or negative variability with the thickness value of the corresponding layer in the pre-improved emissivity structure is at most 40%, in particular at most 30%, for example at most 10%.

In particular, the simplex algorithm presented hereinabove for step 1. and step 3. of sub-step iv. in the context of the reflective portion applies mutatis mutandis in step 1. of sub-step iv. in the context of the emissivity portion, notwithstanding that the last dimension represents χ_{A}.

### Step c

According to an embodiment of the invention, the value A_{FM} (λᵢ) is 0.5 for any wavelength of the range of reflection wavelengths.

In particular, for the calculation of the performance value χ_{A}, a system formed by air, the improved structure and a substrate as defined before, is considered.

### Step d

According to an embodiment of the invention, the value χ_{Aref} is equal to or less than 5. The lower the value χ_{Aref}, the higher the refrigeration performances will be. The refrigeration effect is obtained starting from a value χ_{Aref} of 5.

According to an embodiment of the invention, when the value χ_{A} has a value lower than or equal to a reference value χ_{Aref}, the automated means implement the following sub-steps to obtain the emitting portion of the daytime radiative device:
bringing the layers B and C together to obtain a superposition of a compiled layer B and a compiled layer C, in particular removal of the compiled layer B,
obtaining the emitting portion of the daytime radiative device. Indeed, the Inventors have unexpectedly discovered that the emissivity performances of the emitting portion were related to the amount of material of by each layer. Even though the determination of the thickness of each layer B and C requires the insertion of new layers, the alternation resulting therefrom has a low impact unlike the amount of total material of each layer which is determined. In this respect, the layers of the same material (B and C) are combined to obtain compiled layers B and C during the determination of the structure, allows an easier and less expensive subsequent manufacture of the emitting portion. Furthermore, as has already been mentioned hereinabove, the layers B of the reflective portion combined with the layers C of the emitting portion provide necessary performances in terms of emissivity. The layers B of the emitting portion, which are necessary to determine the structure of the emitting portion, are not necessary to obtain the emissivity performances and may be removed from the determined structure. Thus, the manufacturing costs of the emitting portion are therefore further reduced.

According to another aspect, the invention relates to a method for determining the structure of the reflective portion of a daytime radiative cooling device as described before, wherein automated means implement the following steps:
a) providing a base reflection structure, said structure having a thickness and consisting of at least one layer A and/or of at least one layer B, said layer A consisting of a material A selected from among Nb₂O₅, TiO₂ and Ta₂O₅ and said layer B consisting of a material B selected from among SiO₂ and Al₂O₃,
b) determining an improved reflection structure by means of the following sub-steps:
i. selecting a wavelength whose reflection is to be improved, said wavelength being selected from a range of reflection wavelengths from 260 nm to 2,500 nm,
ii. selecting a material to be inserted according to the following criteria:
said material to be inserted is selected from among those of the material B if the base reflection structure consists of a layer A,
said material to be inserted is selected from among those of the material A if the base reflection structure consists of a layer B,
said material to be inserted is selected from among those of the material A or from those of the material B in all other cases,
iii. determining the number of new layers to be inserted into the base reflection structure and their position within the base reflection structure, a new layer consisting of said material to be inserted and inserted according to the thickness of the base reflection structure,
said number and said position being determined according to the selected wavelength and the selected material to be inserted, iv. determining the thickness of the or each new layer and obtaining an improved reflection structure in which the new layer(s) is/are incorporated,
c) determining a reflection performance value χ_{R} of the improved structure using the following formula

$${χ}_{R} = \frac{1}{\sqrt{N}} \sqrt{{\sum }_{i = 1}^{N} \frac{{( {R}_{SRA} ( {λ}_{i} ) - {R}_{F M} ( {λ}_{i} ) )}^{2}}{{tol}^{2}}} \qquad [ Math 2 ]$$

where
λᵢ is a wavelength (in nanometres) in the range of reflection wavelengths,
N is the number of wavelengths in the range of reflection wavelengths,
R_{SRA}(λᵢ) is the coefficient of reflection obtained for the improved reflection structure at the wavelength λᵢ,
R_{FM}(λᵢ) is the coefficient of reflection to be reached at the wavelength Ai, and tol has a value of 0.1,
d) if χ_{R} has a value lower than or equal to a reference value χ_{Rref}, determining the improved reflection structure as corresponding to the reflective portion of the daytime radiative device; or
if χ_{R} has a value higher than the reference value χ_{Rref}, repeating steps b) to d) while selecting the base reflection structure as being the improved reflection structure determined in step b).

The embodiments described before in connection with the determination of the reflective portion apply mutatis mutandis to this aspect of the invention.

According to another aspect, the invention relates to a method for determining the emitting portion of a daytime radiative device as described before, wherein automated means implementing the following steps:
a) providing a base emissivity structure, said structure having a thickness and consisting of at least one layer C and/or of at least one layer B, said layer C consisting of a material C selected from among Nb₂O₅, SiO₂, SiC, TiO₂, Ta₂O₅ and Al₂O₃ and said layer B consisting of a material B selected from among SiO₂ and Al₂O₃, the material C being different from the material B, preferably one of the materials B and C is SiO₂,
b) determining an improved emissivity structure by means of the following sub-steps:
i. selecting a wavelength whose emissivity is to be improved, said wavelength being selected from a range of reflection wavelengths from 7,500 nm to 13,300 nm,
ii. selecting a material to be inserted according to the following criteria:
said material to be inserted is selected from among those of the material B if the base emissivity structure consists of a layer C,
said material to be inserted is selected from among those of the material C if the base emissivity structure consists of a layer B,
said material to be inserted is selected from among those of the material C or from those of the material B in all other cases,
iii. determining the number of new layers to be inserted into the base emissivity structure and their position within the base emissivity structure, a new layer consisting of said material to be inserted and inserted according to the thickness of the base emissivity structure,
said number and said position being determined according to the selected wavelength and the selected material to be inserted,
iv. determining the thickness of the or each new layer, and obtaining an improved emissivity structure in which the new layer(s) is/are incorporated,
c) determining an absorption performance value χ_{A} of the improved structure using the following formula

$${χ}_{A} = \frac{1}{\sqrt{N}} \sqrt{{\sum }_{i = 1}^{N} \frac{{( {A}_{SEA} ( {λ}_{i} ) - {A}_{F M} ( {λ}_{i} ) )}^{2}}{{tol}^{2}}} \qquad [ Math 37 ]$$

where
λᵢ is a wavelength (in nanometres) in the emission wavelength range,
N is the number of wavelengths in the emission wavelength range,
A_{SRA}(λᵢ) is the coefficient of absorption obtained for the improved structure at the spectral wavelength λᵢ,
A_{FM}(λᵢ) is the coefficient of absorption to be reached at the spectral wavelength Ai, and tol has a value of 0.1,
d) if χ_{A} has a value lower than or equal to a reference value χ_{Aref}, determining the improved emissivity structure as corresponding to the emitting portion of the daytime radiative device; or
if χ_{A} has a value higher than the reference value χ_{Aref}, repeating steps b) to d) while selecting the base emissivity structure as being the improved emissivity structure determined in step b).

The embodiments described before in connection with the determination of the emitting portion apply mutatis mutandis to this aspect of the invention.

The invention also relates to a method for determining the structure of a daytime radiative cooling device as defined before, said daytime radiative device comprising an emitting portion and a reflective portion, wherein automated means implement the following steps:
determining the structure of the reflective portion by means of the method defined before,
determining the structure of the emitting portion by means of the method defined before,
superposing the reflective portion over the emitting portion and obtaining the daytime radiative device, and in particular adjusting the total thickness of the daytime radiative device, in particular by means of a genetic algorithm, in particular coupled to a simplex algorithm, applied to the entire structure of the daytime radiative cooling device,
obtaining the structure of the daytime radiative device.

In particular, the genetic algorithm used in this aspect of the invention may correspond to that one described for step 1. of sub-step iv. in the context of the reflective portion, notwithstanding that:
in step aa), each parent individual corresponds to a daytime radiative device comprising all the layers of the daytime radiative device obtained hereinbefore, the thickness value of each layer of an individual being generated stochastically with a positive or negative variability of at most 50%, with the thickness value of the corresponding layer of said daytime radiative device,
in step dd), the crossing of the parent individuals is carried out while considering all of the layers forming each parent individual, so that the thickness of all of the layers is variable between the parent individuals and the child individuals, and
in step dd), the mutation of the child individuals is carried out on all of the layers forming each child individual,
in steps bb) and ee), it is determined for each individual (parent or child) both the absorption performance value χ_{A} and the reflection performance value χ_{R}, said performance values being compared with the reference values χ_{Aref} and χ_{Rref} respectively during steps cc) and ff).

In particular, the positive or negative variability with the thickness value of the corresponding layer in the daytime radiative device is at most 40%, in particular at most 30%, for example at most 10%.

In particular, the simplex algorithm used in this aspect of the invention may correspond to that one described for step 1. of sub-step iv. in the context of the reflective portion, notwithstanding that in the N dimensions, there is a dimension for the values of χ_{A}, a dimension for the values of χ_{R}, and a dimension for each layer of the daytime radiative device.

According to another aspect, the invention relates to a method for manufacturing a daytime radiative cooling device as defined before, said daytime radiative device comprising a reflective portion, said method comprising the following steps:
a) providing a structure of the reflective portion or determining a structure of the reflective portion according to the previously-described method,
b) successively depositing each layer A and B according to the structure of the reflective portion.

In particular, during step b), the deposition may be carried out over a substrate as described before.

In particular, the deposition of the layers A and B during steps b) may be carried out by magnetron cathode sputtering.

According to another aspect, the invention relates to a method for manufacturing a daytime radiative cooling device as defined before, said daytime radiative device further comprising an emitting portion, said method comprising the following steps:
a) providing the structure of the reflective portion or determining the structure of the emitting portion according to the previously-described method,
b) providing the structure of the emitting portion or determining the structure of the emitting portion according to the previously-described method,
c) successively depositing each layer C and B following the structure of the emitting portion, and
d) successively depositing each layer A and B following the structure of the reflective portion.

In particular, during step c), depending on the structure of the emitting portion, a compiled layer C will be deposited or a compiled layer C and a compiled layer B will be deposited or an alternation of several layers C and of several layers B will be deposited.

In particular, during step c), the deposition may be carried out over a substrate as described before.

In particular, the deposition of the layers A and B during steps d) and C and D during step c) may be carried out by magnetron cathode sputtering.

The deposition of the layers A, B and C during steps c) and d) may be carried out by magnetron cathode sputtering. In this embodiment, a step of preparing the substrate may be carried out chemically. In particular, this chemical treatment may be based on hydrofluoric acid with a concentration of 5% and carried out for 30 seconds. Afterwards, the substrate may be rinsed in 3 baths of ultrapure water for 1 minute each. Then, the substrate may be dried under a stream of pure nitrogen to remove any trace of water. In addition, the substrate may be rinsed under a stream of propan-1-ol, to remove any trace of organic molecule and water. The substrate is placed on a suitable substrate holder. It is introduced in a deposition chamber under, i.e. with a pressure of 2 mTorr (1 mTorr=0.133322 pascal). The chamber comprises at least one cathode and one single anode. Afterwards, the pressure is raised to a value of 2 to 50 mTorr, preferably to 20 mTorr, the temperature is set from 25° C. to 200° C. and an argon stream of 1 to 40 sccm (standing for “standard cubic centimetre per minute”), preferably at 10 sccm, even more preferably 20 sccm, is applied in the chamber on the substrate which is rotating at 10 to 50 revolutions per minute, preferably at 20 revolutions per minute. This step allows obtaining a uniform temperature throughout the chamber (including the substrate). It may last for one hour. Afterwards, the initialisation of a cold plasma is carried out by injecting a working power of at least 30 percent (for example from 10 W to 400 W) of the maximum power on the cathode with an argon pressure of 10 to 50 m Torr, preferably 20 m Torr. In particular, the maximum power may be 300 W. Afterwards, the pressure is decreased to a value of 2 to 10 mTorr per successive steps. In particular, the pressure is decreased by successive steps of 5 mTorr. Each step is reached, for example, in less than 10 seconds, in particular in less than 5 seconds. Thus, a stabilisation of the plasma is reached.

Afterwards, for each material A, B or C, a layer of a corresponding material is deposited under a cold plasma stream of 100% argon or a mixture of argon and oxygen. The deposition is carried out at a pressure close to that of the vacuum, from 1 to 5 m Torr. The material A, B or C is arranged on the or one of the cathodes thereby forming a target which is sprayed by the plasma. When several materials are to be deposited in turn, each is arranged on a different cathode and each target is subjected to plasma in turn. The atoms of the material A, B or C torn off the target by the plasma are transported and then deposited over the substrate, or over a previously formed layer. The duration of the deposition (and therefore the duration during which the material is subjected to the plasma) depends on the thickness of the layer of A, B or C and of the used material A, B or C. The deposition rate, i.e. the rate at which the thickness of the layer in formation increases, is comprised in particular from 0.01 to 0.1 nm/s. The temperature of the substrate during deposition is in particular from 25° C. to 250° C., in particular at 200° C. The plasma could change according to the used material A, B or C. The gas mixture forming the plasma may also change during the deposition process according to the material to be deposited. The ratio between argon and oxygen in the plasma stream is in particular from 1:1 to 8:1, in particular it amounts to 5:1. The plasma stream of 100% argon is in particular applied with a mass flow rate of 30 to 50 sccm, in particular of 40 sccm. As regards the stream of the argon and oxygen mixture, each gas may be applied with a particular mass flow rate. This mass flow rate depends on the used material A, B or C. In particular, for oxygen, the mass flow rate may be from 5 to 15 sccm, for example 7 sccm for a SiO₂ layer and 12 sccm for a Nb₂₀₅ layer. As regards argon, the mass flow rate may be from 30 to 50 sccm, in particular 40 for a SiO₂ or Nb₂₀₅ layer. The power applied to each target ranges from 10W to 400 W. For example, it may be 100 W for SiO₂ and 325 W for Nb₂O₅.

The invention will be better understood in light of the following figures and examples.

### BRIEF DESCRIPTION OF THE FIGURES

FIG. 1 is a flowchart showing the steps of the method for determining the structure of a reflective portion or of an emitting portion of a daytime radiative device according to the invention.

FIG. 2 is a flowchart showing the steps for determining the performance values χ_{R} and χ_{A} in the context of the method for determining the structure of a reflective portion or of an emitting portion of one daytime radiative device according to the invention.

FIG. 3 is a flowchart showing the steps of determining the selection of a wavelength in the context of the method for determining the structure of a reflective portion or of an emitting portion of a daytime radiative device according to the invention.

FIG. 4 is a flowchart showing the steps of determining the optimum positions for inserting the new layer(s) in the context of the method for determining the structure of a reflective portion or of an emitting portion of a device daytime radiative according to the invention.

FIG. 5 is a flowchart showing the steps of executing a genetic algorithm in the context of the method for determining the structure of a reflective portion or of an emitting portion of a daytime radiative device according to the invention.

FIG. 6 is a flowchart showing the steps of executing a simplex algorithm in the context of the method for determining the structure of a reflective portion or of an emitting portion of a daytime radiative device according to the invention.

FIG. 7 is a graph showing the reflection spectrum of the wavelengths 260 nm to 2,500 nm by a daytime radiative cooling device according to the invention. The radiance of the solar spectrum AM1.5 is also shown. The x-axis corresponds to the wavelengths. The Y-axis to the left corresponds to the coefficient of reflection (1 corresponds to 100% reflection). The Y-axis to the right corresponds to the radiance of the solar spectrum AM1.5 in W·m⁻²·Nm⁻¹.

FIG. 8 is a graph showing the absorption spectrum of the wavelengths 7,500 to 13,500 nm by a daytime radiative cooling device according to the invention. The atmospheric transmittance is also shown. The x-axis corresponds to the wavelengths. The Y-axis to the left corresponds to the absorption (1 corresponds to 100% absorption). The Y-axis to the right corresponds to the atmospheric transmittance (transmission coefficient in intensity).

FIG. 9 is a graph showing the reflection and absorption spectra of the wavelengths 1 to 14,000 nm by a daytime radiative cooling device according to the invention. The x-axis corresponds to the wavelengths. The Y-axis to the left corresponds to the coefficient of reflection. The Y-axis to the right corresponds to the absorption.

FIG. 10 is a graph showing the refractive index n (y-axis to the left) and the extinction coefficient k (y-axis to the right) as a function of the wavelengths of the range 7,500 to 13,300 nm (x-axis) for SiO₂.

FIG. 11 is a graph showing the refractive index n (y-axis to the left) and the extinction coefficient k (y-axis to the right) as a function of the wavelengths of the range 7,500 to 13,300 nm (x-axis) for SiC.

FIG. 12a is a graph showing the refractive index (y-axis to the left) and the extinction coefficient (y-axis to the right) as a function of the wavelengths of the range 250 nm to 2,500 nm (x-axis) for Nb₂O₅.

FIG. 12b is a graph showing the refractive index n (y-axis to the left) and the extinction coefficient k (y-axis to the right) as a function of the wavelengths of the range 7,500 to 13,300 nm (x-axis) for Nb₂O₅.

FIG. 13a is a graph showing the refractive index n (y-axis to the left) and the extinction coefficient k (y-axis to the right) as a function of the wavelengths of the range 250 nm to 2,500 nm (x-axis) for Al₂O₃.

FIG. 13b is a graph showing the refractive index n (y-axis to the left) and the extinction coefficient k (y-axis to the right) as a function of the wavelengths of the range 7,500 to 13,300 nm (x-axis) for Al₂O₃.

FIG. 14a is a graph showing the refractive index n (y-axis to the left) and the extinction coefficient k (y-axis to the right) as a function of the wavelengths of the range 250 nm to 2,500 nm (x-axis) for TiO₂.

FIG. 14b is a graph showing the refractive index n (y-axis to the left) and the extinction coefficient k (y-axis to the right) as a function of the wavelengths of the range 7,500 to 13,300 nm (x-axis) for TiO₂.

FIG. 15a is a graph showing the refractive index n (y-axis to the left) and the extinction coefficient k (y-axis to the right) as a function of the wavelengths of the range 250 nm to 2,500 nm (x-axis) for Ta₂₀₅.

FIG. 15b is a graph showing the refractive index n (y-axis to the left) and the extinction coefficient k (y-axis to the right) as a function of the wavelengths of the range 7,500 to 13,300 nm (x-axis) for Ta₂₀₅.

FIG. 16 is a graph showing the total performance R_{AM1.5} in percentage for the reflection of the wavelengths from 260 nm to 2,500 nm as a function of the number of layers of a cooling radiative device according to the invention consisting of a reflective portion (alternation of Nb₂O₅ and SiO₂ layers) and an emitting portion. In the used device, the number of layers of the reflective portion was variable and the emitting portion consisted of one single layer of SiC with a thickness of 4.995 μm. One could see that starting from 70 layers of the reflective portion, a total performance of at least 90% is obtained. Each cooling radiative device for which the total performance is lower than 90% is represented by a point, and each device for which the total performance is higher than 90% is represented by a star.

FIG. 17 is a graph showing the balance temperature in Celsius (° C.) as a function of the number of layers of the number of layers of a cooling radiative device according to the invention consisting of a reflective portion (alternation of Nb₂O₅ and SiO₂ layers) and an emitting portion. In the used device, the number of layers of the reflective portion was variable and the emitting portion consisted of one single layer of SiC with a thickness of 4.995 μm. The balance temperature represents the difference between the equilibrium temperature of the device and the external temperature. In this case, the considered external temperature was 300K. One could see that starting from 70 layers of the reflective portion, a balance temperature of 0 or less is obtained, and therefore a refrigeration effect.

FIG. 18 is a graph showing two reflection spectra of the wavelengths from 260 nm to 2,500 nm: a target reflection spectrum (black line curve), called figure of merit, and a reflection spectrum (clear grey line curve) obtained by experimental measurements using a “Universal Reflectance Accessy” (URA) module of a Lambda 1050 spectrophotometer (Perkin Elmer®) on a reflective portion of a daytime device according to the invention of 72 layers. The X-axis corresponds to the wavelengths from 0 to 3,000 nm. The Y-axis corresponds to the reflection percentage.

FIG. 19 shows three histograms (a, b and c) representing the theoretical thickness (black bar) and the obtained thickness (white bar) for each layer of a reflective portion of a daytime radiative device according to the invention consisting of 72 layers (histogram (a): layers 1 to 23; histogram (b): layers 24 to 47; histogram (c): layers 48 to 72). On each histogram, the Y-axis represents the thickness of the layers (in nm) and the X-axis represents the number of the layer. The layer bearing the number 1 is the lowest layer of the reflective portion, namely the first deposited layer, and the layer bearing the number 72 is the uppermost layer, namely the last deposited layer.

### EXAMPLES

### Example 1: Determination of the Reflective Portion and of the Emitting Portion of a Cooling Radiative Device

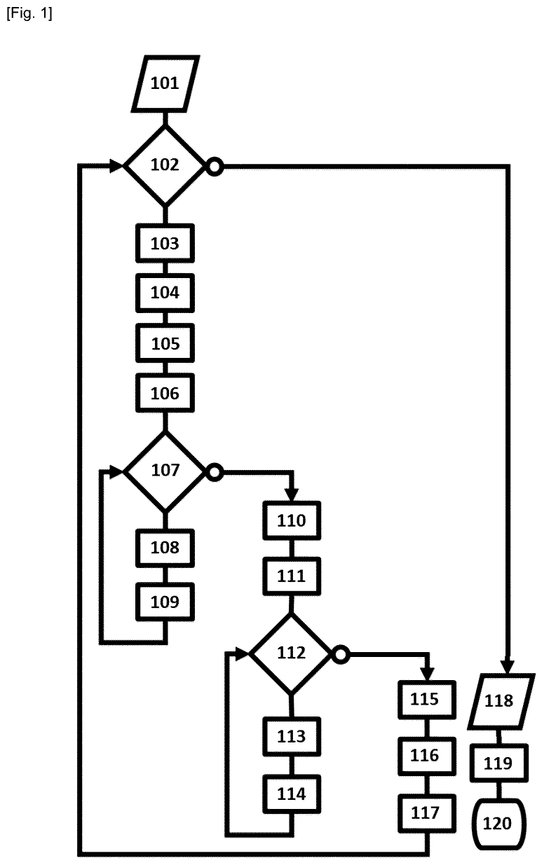

The Inventors have developed a method allowing determining the reflective and emitting portions of a cooling radiative device. This common method is illustrated in FIGS. 1 to 7. The input parameters of the method are modified according to the portion, reflective or emitting, whose structure is determined.

The first step 101 illustrated in FIG. 1 corresponds to the initialisation of the parameters specific to each portion whose structure is determined (materials A/B/C of the base structure and thickness(s)). For the reflective portion, the base structure corresponds to a SiO₂ layer with a thickness of 500 nm. For the emitting portion, the base structure corresponds to a SiO₂ layer with a thickness of 500 nm.

The second step 102 is a main loop with a pass condition test in step 118. In the context of the reflective portion, this consists in having reflection performances χ_{R} lower than χ_{Rref}=1. For the emitting portion, this consists in having a reflection performance χ_{A} lower than χ_{Aref}=5.

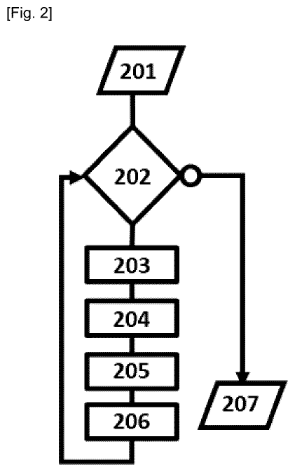

The values χ_{R} and χ_{A} are established using a method described in FIG. 2. Step 201 corresponds to the input of the parameters of the tested structure: thickness and refractive index of the material of each layer forming the tested structure. The refractive index of air and of a Si substrate being also considered. Step 202 corresponds to a test loop of all of the wavelengths of the considered range: from 260 nm to 2,500 nm for the reflective portion and 7,500 to 13,300 for the emitting portion. Step 203 corresponds to the allocation of the number of transfer matrices necessary to describe the considered structure (a 2×2 matrix for each thin layer). Step 204 corresponds to the multiplication of the transfer matrices to obtain the resulting matrix of the substrate assembly, tested structure and air. Step 205 corresponds to the calculation of the observable reflection R, transmission T and absorption A quantities based on the resulting matrix. Step 206 corresponds to the calculation of the values χ_{R} and χ_{A} according to the equations mentioned hereinabove in the description. For these calculations, the figure of merit shows a spectral reflection quantity R of 1 for each wavelength from 260 nm to 2,500 nm, and an absorption spectral quantity A of 1 for each wavelength from 7,500 nm to 13,000 nm. Step 207 corresponds to the recording of the values R, T and A for each structure and of the values χ_{R} and χ_{A}.

Step 103 corresponds to the calculation of the reflection R, transmission T and absorption A optical quantities of the tested structure. These quantities are obtained by executing steps 201 to 205 described before.

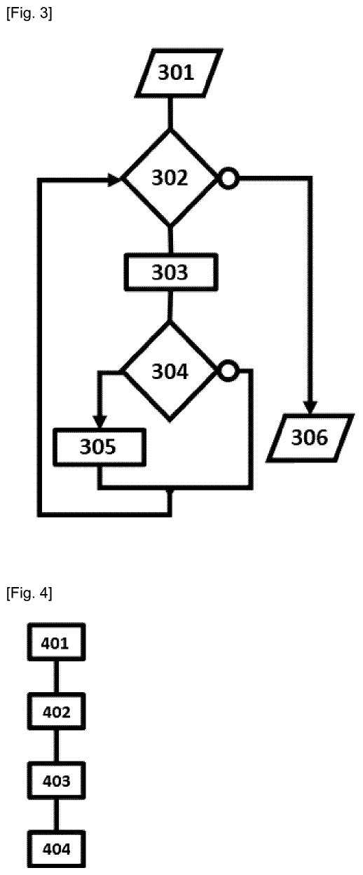

Step 104 corresponds to the selection of the length used in step 106 during the Needle insertion method. This step is detailed in FIG. 3. In FIG. 3, step 301 corresponds to the recovery of all of the spectral data of the tested structure (R, T and A) and those of a figure of merit. The figure of merit has a reflection spectral quantity R of 1 for each wavelength from 260 nm to 2,500 nm, and an absorption spectral quantity A of 1 for each wavelength from 7,500 nm to 13000 nm. Step 302 corresponds to a test loop of all of the wavelengths of the considered range: from 260 nm to 2,500 nm for the reflective portion and 7,500 to 13,300 for the emitting portion. For each wavelength, steps 303 and 304, and optionally 305, are carried out. Step 303 corresponds to the calculation of the difference between the spectral data and the figure of merit at the given wavelength. Step 304 corresponds to the comparison of this value with the maximum difference value found before. By default, the maximum difference value is 0. Step 305 is executed if the comparison gives a difference greater than the maximum difference. This value then becomes the new maximum difference for the next iterations. When all of the wavelengths have been tested, step 306 is executed and corresponds to the selection of the wavelength for which the maximum difference has been preserved.

Step 105 corresponds to the selection of the material that will form the new layers inserted into the base structure. For the reflective portion, this material corresponds to that having a refractive index value furthest from that of the host material of the base structure. Since the host material is SiO₂, the selected material is Nb₂O₅. For the emitting portion, SiC has been selected.

Step 106 corresponds to the search for the optimum positions in the thickness of the base structure where the new layers are inserted. This step is detailed in FIG. 4.

Step 401 corresponds to the calculation of the spatial derivative of the spectral quantity R as a function of the thickness of the base structure while considering the refractive index of the material of the new layers and the selected wavelength. Step 402 corresponds to the determination of the number of new layers to be inserted into the base reflection structure as corresponding to the number of times the derivative is cancelled by passing from a negative extremum to a positive extremum. Step 403 corresponds to the determination of the position of the new layer(s) to be inserted into the base reflection structure as corresponding to each of the values of z for which the derivative is cancelled by passing from a negative extremum to a positive extremum. Step 404 corresponds to the recording of the values of the determined thicknesses and to the redistribution of the thicknesses as a function of the position where the new layers will be inserted.

Step 107 is a conditional loop for passage to step 110. In the context of the reflective portion, this consists in having reflection performances χ_{R} lower than χ_{Rref} (χ_{Rref} is 1). For the emitting portion, this consists in having the reflection performances χ_{A} lower than χ_{Aref} (χ_{Aref} is 5).

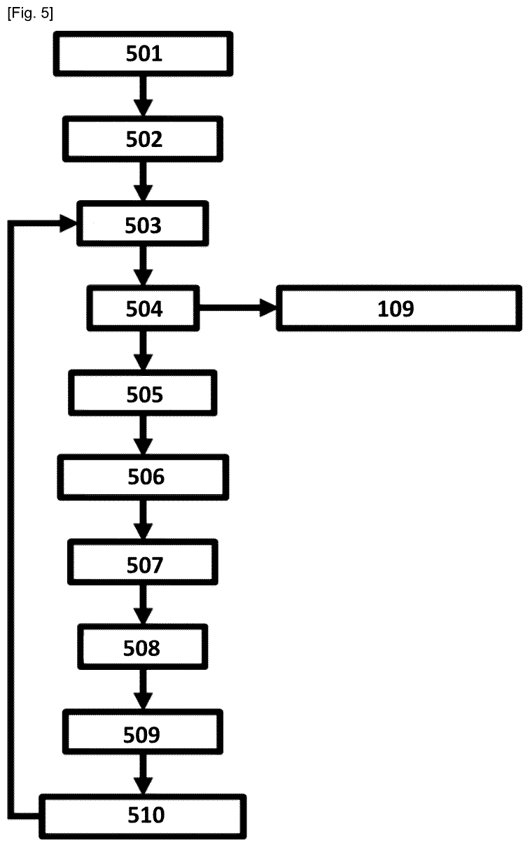

Step 108 corresponds to the application of a genetic algorithm to minimise the value χ_{R} Or χ_{A} of the considered structure, while considering only the new layers. The detail of this step is given in FIG. 5. Step 501 corresponds to the initialisation of the initial population of parent individuals each corresponding to a generation of random thicknesses for the or each new layer. Each thickness is comprised between 1 and 1,750 nm. In step 502, the value χ_{R} Or χ_{A} of the parent individuals is calculated using the method described in FIG. 2. Step 503 is a sorting of the parent individuals according to their value χ_{R} Or χ_{A}. Step 504 is a conditional step for passage to step 109. The first condition for passage to step 109 is whether the value of the parent individual having the lowest value χ_{R} Or χ_{A} is lower than the value χ_{Rref} Or χ_{Aref} respectively. The second condition for passage to step 109 is whether 150,000 iterations of steps 505 to 507 have been carried out. Step 505 corresponds to the stochastic roulette selection of the parent individuals. During this step, a “scaling” algorithm is used, which is a scaling technique imposed by the roulette selection mode. This consists of a truncated sigma scaling with the type of the coefficients scal=1, scalvarp=0.5, scalvarp1=1, scalvarp2=2. Step 506 corresponds to the crossing of these individuals according to the preceding selection in order to obtain child individuals. These crossings are sbx crossings according to the probability of applying a crossing to a parent pc=0.6. Step 507 corresponds to the mutation of the child individuals by mutation and the obtainment of an offspring of child individuals. The mutation applied to each child is a non-uniform mutation controlled by the parameter b=1 (b=1 exploratory otherwise Local search b=25) and the probability of applying a mutation to an individual pm=0.005. At step 508, the value χ_{R} Or χ_{A} of the child individuals of the offspring is calculated using the method described in FIG. 2. Step 509 is a sorting of the child individuals of the offspring according to their value χ_{R} Or χ_{A}. Step 510 allows keeping the best child individuals of the previous generation if the best individual of the offspring has a value χ_{R} Or χ_{A} lower than the best individual of the previous generation.

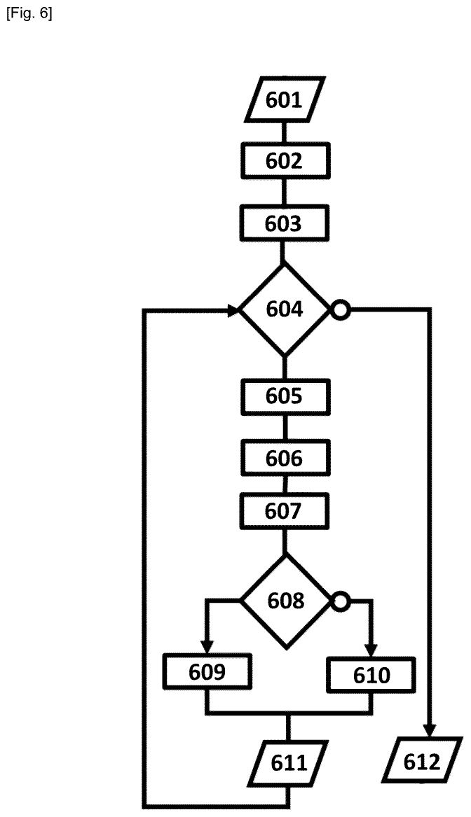

Step 109 corresponds to the application of a simplex algorithm to minimise the value χ_{R} Or χ_{A} of the child individuals of the best offspring obtained in step 108. This step is described in detail in FIG. 6. Step 601 corresponds to the collection of the data of the child individuals of the best offspring. Step 602 corresponds to the sorting of the child individuals according to their value χ_{R} Or χ_{A} by the PIKSRT subroutine, based on the Document “Numerical recipes in fortran 77”.

Step 603 corresponds to the definition of the simplex vertices based on the data of the individuals. Step 604 is a conditional loop with a test of the value χ_{R} Or χ_{A}, according to the considered structure, or of 55,000 iterations of steps 605 to 610 to pass to step 611. Step 606 corresponds to the sorting of the heights of the vertices of the simplex. Step 607 corresponds to the calculation of the value χ_{R} or χ_{A}, according to the considered structure, for each simplex. Step 608 corresponds to the reflection from the highest point for each simplex, leading, depending on the obtained result, to step 609 of extrapolation of the simplex by a 2 factor or to step 610 of contraction of the simplex by a 0 factor, Step 611 corresponds to obtaining, following steps 609 or 610, an improvement in the simplex vertices. Step 612 corresponds to the recording of the individual thickness data retained for the rest of the process.

Step 110 is optional and corresponds to merging of contiguous layers of the same material.

Step 111 is optional and corresponds to the removal of the layers with an excessively fine thickness.

Step 112 is a conditional loop for passage to step 115. In the context of the reflective portion, this consists in having reflection performances χ_{R} lower than χ_{Rref}=1. For the emitting portion, this consists in having reflection performances χ_{A} lower than χ_{Aref}=5.

Steps 113 and 114 are based on steps 108 and 109. In these steps, the considered individuals correspond to the entire structures, including the new layers and the host layers.

Steps 115 and 116 correspond to steps 110 and 111 respectively.

Step 117 corresponds to step 103.

Step 118 corresponds to recording the data (layers, materials, thicknesses) relating to the structure of the reflective portion or of the structure of the emitting portion. As regards the emitting portion, the automated means have implemented in step 119 the compilation of the layers of material B and C, and the removal of the compiled layer B.

Step 120 is a step of stopping the automated means.

A daytime radiative cooling device determined by the aforementioned method had the following values χ_{R} and χ_{A}: χ_{R}=0.275 and χ_{A}=1.095. The different layers of this device are described in the following table:

TABLE 4

| Number of | Thickness | |
|---|---|---|
| the layer | (in nm) | Material |
| 1 | 247.0 | Nb₂O₅ |
| 2 | 267.0 | SiO₂ |
| 3 | 271.5 | Nb₂O₅ |
| 4 | 30.8 | SiO₂ |
| 5 | 27.5 | Nb₂O₅ |
| 6 | 57.1 | SiO₂ |
| 7 | 70.2 | Nb₂O₅ |
| 8 | 22.0 | SiO₂ |
| 9 | 25.5 | Nb₂O₅ |
| 10 | 251.2 | SiO₂ |
| 11 | 78.7 | Nb₂O₅ |
| 12 | 118.3 | SiO₂ |
| 13 | 61.0 | Nb₂O₅ |
| 14 | 325.6 | SiO₂ |
| 15 | 591.3 | Nb₂O₅ |
| 16 | 117.1 | SiO₂ |
| 17 | 201.7 | Nb₂O₅ |
| 18 | 301.3 | SiO₂ |
| 19 | 53.3 | Nb₂O₅ |
| 20 | 4.6 | SiO₂ |
| 21 | 274.3 | Nb₂O₅ |
| 22 | 70.1 | SiO₂ |
| 23 | 3.2 | Nb₂O₅ |
| 24 | 131.1 | SiO₂ |
| 25 | 94.9 | Nb₂O₅ |
| 26 | 139.7 | SiO₂ |
| 27 | 125.6 | Nb₂O₅ |
| 28 | 166.4 | SiO₂ |
| 29 | 55.2 | Nb₂O₅ |
| 30 | 64.6 | SiO₂ |
| 31 | 3.8 | Nb₂O₅ |
| 32 | 84.5 | SiO₂ |
| 33 | 76.3 | Nb₂O₅ |
| 34 | 20.9 | SiO₂ |
| 35 | 8.6 | Nb₂O₅ |
| 36 | 96.1 | SiO₂ |
| 37 | 91.6 | Nb₂O₅ |
| 38 | 35.7 | SiO₂ |
| 39 | 31.7 | Nb₂O₅ |
| 40 | 24.6 | SiO₂ |
| 41 | 22.3 | Nb₂O₅ |
| 42 | 2.7 | SiO₂ |
| 43 | 32.2 | Nb₂O₅ |
| 44 | 13.5 | SiO₂ |
| 45 | 25.8 | Nb₂O₅ |
| 46 | 215.4 | SiO₂ |
| 47 | 99.3 | Nb₂O₅ |
| 48 | 36.4 | SiO₂ |
| 49 | 65.8 | Nb₂O₅ |
| 50 | 65.2 | SiO₂ |
| 51 | 42.4 | Nb₂O₅ |
| 52 | 135.3 | SiO₂ |
| 53 | 1.3 | Nb₂O₅ |
| 54 | 204.5 | SiO₂ |
| 55 | 6.6 | Nb₂O₅ |
| 56 | 5.1 | SiO₂ |
| 57 | 22.6 | Nb₂O₅ |
| 58 | 2.8 | SiO₂ |
| 59 | 1.8 | Nb₂O₅ |
| 60 | 72.6 | SiO₂ |
| 61 | 195.5 | Nb₂O₅ |
| 62 | 290.1 | SiO₂ |
| 63 | 166.3 | Nb₂O₅ |
| 64 | 7.0 | SiO₂ |
| 65 | 60.6 | Nb₂O₅ |
| 66 | 140.8 | SiO₂ |
| 67 | 17.6 | Nb₂O₅ |
| 68 | 36.8 | SiO₂ |
| 69 | 2.2 | Nb₂O₅ |
| 70 | 6.1 | SiO₂ |
| 71 | 25.2 | Nb₂O₅ |
| 72 | 135.3 | SiO₂ |
| 73 | 149.4 | Nb₂O₅ |
| 74 | 133.4 | SiO₂ |
| 75 | 115.6 | Nb₂O₅ |
| 76 | 239.8 | SiO₂ |
| 77 | 74.0 | Nb₂O₅ |
| 78 | 1.2 | SiO₂ |
| 79 | 115.6 | Nb₂O₅ |
| 80 | 213.3 | SiO₂ |
| 81 | 81.9 | Nb₂O₅ |
| 82 | 28.2 | SiO₂ |
| 83 | 112.8 | Nb₂O₅ |
| 84 | 341.4 | SiO₂ |
| 85 | 19.3 | Nb₂O₅ |
| 86 | 1.6 | SiO₂ |
| 87 | 259.9 | Nb₂O₅ |
| 88 | 270.3 | SiO₂ |
| 89 | 29.3 | Nb₂O₅ |
| 90 | 4.2 | SiO₂ |
| 91 | 39.8 | Nb₂O₅ |
| 92 | 14.1 | SiO₂ |
| 93 | 139.1 | Nb₂O₅ |
| 94 | 57.3 | SiO₂ |
| 95 | 4.2 | Nb₂O₅ |
| 96 | 9.4 | SiO₂ |
| 97 | 13.7 | Nb₂O₅ |
| 98 | 143.3 | SiO₂ |
| 99 | 23.8 | Nb₂O₅ |
| 100 | 8.7 | SiO₂ |
| 101 | 113.8 | Nb₂O₅ |
| 102 | 107.3 | SiO₂ |
| 103 | 150.5 | Nb₂O₅ |
| 104 | 19.5 | SiO₂ |
| 105 | 11.2 | Nb₂O₅ |
| 106 | 76.3 | SiO₂ |
| 107 | 106.8 | Nb₂O₅ |
| 108 | 258.5 | SiO₂ |
| 109 | 133.2 | Nb₂O₅ |
| 110 | 119.3 | SiO₂ |
| 111 | 1.3 | Nb₂O₅ |
| 112 | 6.3 | SiO₂ |
| 113 | 8.8 | Nb₂O₅ |
| 114 | 12.9 | SiO₂ |
| 115 | 7.7 | Nb₂O₅ |
| 116 | 50.3 | SiO₂ |
| 117 | 89.4 | Nb₂O₅ |
| 118 | 222.3 | SiO₂ |
| 119 | 106.0 | Nb₂O₅ |
| 120 | 52.7 | SiO₂ |
| 121 | 47.3 | Nb₂O₅ |
| 122 | 172.2 | SiO₂ |
| 123 | 38.3 | Nb₂O₅ |
| 124 | 26.9 | SiO₂ |
| 125 | 2.8 | Nb₂O₅ |
| 126 | 3.1 | SiO₂ |
| 127 | 139.8 | Nb₂O₅ |
| 128 | 232.8 | SiO₂ |
| 129 | 48.5 | Nb₂O₅ |
| 130 | 19.5 | SiO₂ |
| 131 | 94.8 | Nb₂O₅ |
| 132 | 98.2 | SiO₂ |
| 133 | 24.1 | Nb₂O₅ |
| 134 | 131.8 | SiO₂ |
| 135 | 101.5 | Nb₂O₅ |
| 136 | 168.8 | SiO₂ |
| 137 | 88.5 | Nb₂O₅ |
| 138 | 43.7 | SiO₂ |
| 139 | 42.6 | Nb₂O₅ |
| 140 | 76.4 | SiO₂ |
| 141 | 33.0 | Nb₂O₅ |
| 142 | 76.5 | SiO₂ |
| 143 | 64.0 | Nb₂O₅ |
| 144 | 5.7 | SiO₂ |
| 145 | 25.0 | Nb₂O₅ |
| 146 | 115.2 | SiO₂ |
| 147 | 74.6 | Nb₂O₅ |
| 148 | 34.3 | SiO₂ |
| 149 | 129.5 | Nb₂O₅ |
| 150 | 33.1 | SiO₂ |
| 151 | 41.0 | Nb₂O₅ |
| 152 | 24.1 | SiO₂ |
| 153 | 80.8 | Nb₂O₅ |
| 154 | 59.1 | SiO₂ |
| 155 | 80.6 | Nb₂O₅ |
| 156 | 332.1 | SiO₂ |
| 157 | 22.2 | Nb₂O₅ |
| 158 | 54.9 | SiO₂ |
| 159 | 166.0 | Nb₂O₅ |
| 160 | 245.9 | SiO₂ |
| 161 | 168.5 | Nb₂O₅ |
| 162 | 182.7 | SiO₂ |
| 163 | 44.9 | Nb₂O₅ |
| 164 | 13.6 | SiO₂ |
| 165 | 5.5 | Nb₂O₅ |
| 166 | 114.5 | SiO₂ |
| 167 | 48.0 | Nb₂O₅ |
| 168 | 1.8 | SiO₂ |
| 169 | 178.0 | Nb₂O₅ |
| 170 | 12.3 | SiO₂ |
| 171 | 40.0 | Nb₂O₅ |
| 172 | 151.2 | SiO₂ |
| 173 | 149.9 | Nb₂O₅ |
| 174 | 23.5 | SiO₂ |
| 175 | 6.7 | Nb₂O₅ |
| 176 | 258.3 | SiO₂ |
| 177 | 51.8 | Nb₂O₅ |
| 178 | 102.8 | SiO₂ |
| 179 | 14.1 | Nb₂O₅ |
| 180 | 3.8 | SiO₂ |
| 181 | 70.3 | Nb₂O₅ |
| 182 | 109.1 | SiO₂ |
| 183 | 16.2 | Nb₂O₅ |
| 184 | 5.3 | SiO₂ |
| 185 | 5,220.3 | SiC |

Another daytime radiative cooling device determined by the aforementioned method with the following value χ_{Rref}=1 and χ_{Aref}=5 had the following values χ_{R} and χ_{A}: χ_{R}=0.265 and χ_{A}=2.814. The different layers of this device are described in the following table:

TABLE 5

| Number of | Thickness | |
|---|---|---|
| the layer | (in nm) | Material |
| 1 | 201.3 | Nb₂O₅ |
| 2 | 317.8 | SiO₂ |
| 3 | 219.3 | Nb₂O₅ |
| 4 | 32.7 | SiO₂ |
| 5 | 25.2 | Nb₂O₅ |
| 6 | 65.0 | SiO₂ |
| 7 | 77.5 | Nb₂O₅ |
| 8 | 20.2 | SiO₂ |
| 9 | 24.0 | Nb₂O₅ |
| 10 | 246.7 | SiO₂ |
| 11 | 92.4 | Nb₂O₅ |
| 12 | 100.6 | SiO₂ |
| 13 | 72.5 | Nb₂O₅ |
| 14 | 263.1 | SiO₂ |
| 15 | 565.8 | Nb₂O₅ |
| 16 | 130.0 | SiO₂ |
| 17 | 227.3 | Nb₂O₅ |
| 18 | 242.4 | SiO₂ |
| 19 | 51.6 | Nb₂O₅ |
| 20 | 5.3 | SiO₂ |
| 21 | 238.5 | Nb₂O₅ |
| 22 | 60.1 | SiO₂ |
| 23 | 3.0 | Nb₂O₅ |
| 24 | 130.1 | SiO₂ |
| 25 | 78.0 | Nb₂O₅ |
| 26 | 142.3 | SiO₂ |
| 27 | 127.9 | Nb₂O₅ |
| 28 | 164.8 | SiO₂ |
| 29 | 44.7 | Nb₂O₅ |
| 30 | 64.6 | SiO₂ |
| 31 | 4.0 | Nb₂O₅ |
| 32 | 81.3 | SiO₂ |
| 33 | 82.2 | Nb₂O₅ |
| 34 | 20.5 | SiO₂ |
| 35 | 7.0 | Nb₂O₅ |
| 36 | 98.8 | SiO₂ |
| 37 | 74.6 | Nb₂O₅ |
| 38 | 38.1 | SiO₂ |
| 39 | 25.8 | Nb₂O₅ |
| 40 | 28.7 | SiO₂ |
| 41 | 18.9 | Nb₂O₅ |
| 42 | 2.4 | SiO₂ |
| 43 | 33.6 | Nb₂O₅ |
| 44 | 13.5 | SiO₂ |
| 45 | 21.2 | Nb₂O₅ |
| 46 | 248.7 | SiO₂ |
| 47 | 100.8 | Nb₂O₅ |
| 48 | 40.7 | SiO₂ |
| 49 | 60.4 | Nb₂O₅ |
| 50 | 55.1 | SiO₂ |
| 51 | 50.9 | Nb₂O₅ |
| 52 | 113.3 | SiO₂ |
| 53 | 1.5 | Nb₂O₅ |
| 54 | 196.5 | SiO₂ |
| 55 | 7.5 | Nb₂O₅ |
| 56 | 4.2 | SiO₂ |
| 57 | 19.2 | Nb₂O₅ |
| 58 | 3.2 | SiO₂ |
| 59 | 1.7 | Nb₂O₅ |
| 60 | 59.4 | SiO₂ |
| 61 | 224.4 | Nb₂O₅ |
| 62 | 306.3 | SiO₂ |
| 63 | 195.9 | Nb₂O₅ |
| 64 | 6.0 | SiO₂ |
| 65 | 65.0 | Nb₂O₅ |
| 66 | 160.5 | SiO₂ |
| 67 | 14.9 | Nb₂O₅ |
| 68 | 32.4 | SiO₂ |
| 69 | 1.8 | Nb₂O₅ |
| 70 | 5.8 | SiO₂ |
| 71 | 20.7 | Nb₂O₅ |
| 72 | 120.9 | SiO₂ |
| 73 | 159.4 | Nb₂O₅ |
| 74 | 132.8 | SiO₂ |
| 75 | 119.2 | Nb₂O₅ |
| 76 | 212.3 | SiO₂ |
| 77 | 60.5 | Nb₂O₅ |
| 78 | 1.3 | SiO₂ |
| 79 | 103.9 | Nb₂O₅ |
| 80 | 186.9 | SiO₂ |
| 81 | 68.1 | Nb₂O₅ |
| 82 | 25.5 | SiO₂ |
| 83 | 134.8 | Nb₂O₅ |
| 84 | 295.7 | SiO₂ |
| 85 | 15.6 | Nb₂O₅ |
| 86 | 1.9 | SiO₂ |
| 87 | 253.5 | Nb₂O₅ |
| 88 | 296.9 | SiO₂ |
| 89 | 34.4 | Nb₂O₅ |
| 90 | 4.6 | SiO₂ |
| 91 | 34.8 | Nb₂O₅ |
| 92 | 12.8 | SiO₂ |
| 93 | 150.6 | Nb₂O₅ |
| 94 | 46.5 | SiO₂ |
| 95 | 4.5 | Nb₂O₅ |
| 96 | 7.7 | SiO₂ |
| 97 | 13.3 | Nb₂O₅ |
| 98 | 166.3 | SiO₂ |
| 99 | 19.9 | Nb₂O₅ |
| 100 | 10.3 | SiO₂ |
| 101 | 91.1 | Nb₂O₅ |
| 102 | 118.3 | SiO₂ |
| 103 | 125.6 | Nb₂O₅ |
| 104 | 22.2 | SiO₂ |
| 105 | 10.9 | Nb₂O₅ |
| 106 | 66.9 | SiO₂ |
| 107 | 121.9 | Nb₂O₅ |
| 108 | 276.1 | SiO₂ |
| 109 | 127.3 | Nb₂O₅ |
| 110 | 122.6 | SiO₂ |
| 111 | 1.6 | Nb₂O₅ |
| 112 | 5.6 | SiO₂ |
| 113 | 10.5 | Nb₂O₅ |
| 114 | 12.0 | SiO₂ |
| 115 | 9.1 | Nb₂O₅ |
| 116 | 40.6 | SiO₂ |
| 117 | 76.0 | Nb₂O₅ |
| 118 | 250.5 | SiO₂ |
| 119 | 102.7 | Nb₂O₅ |
| 120 | 55.3 | SiO₂ |
| 121 | 38.9 | Nb₂O₅ |
| 122 | 146.6 | SiO₂ |
| 123 | 36.6 | Nb₂O₅ |
| 124 | 22.5 | SiO₂ |
| 125 | 2.3 | Nb₂O₅ |
| 126 | 2.8 | SiO₂ |
| 127 | 119.7 | Nb₂O₅ |
| 128 | 255.3 | SiO₂ |
| 129 | 56.6 | Nb₂O₅ |
| 130 | 22.0 | SiO₂ |
| 131 | 103.3 | Nb₂O₅ |
| 132 | 112.9 | SiO₂ |
| 133 | 27.2 | Nb₂O₅ |
| 134 | 107.4 | SiO₂ |
| 135 | 86.3 | Nb₂O₅ |
| 136 | 174.6 | SiO₂ |
| 137 | 85.5 | Nb₂O₅ |
| 138 | 44.4 | SiO₂ |
| 139 | 39.0 | Nb₂O₅ |
| 140 | 62.0 | SiO₂ |
| 141 | 33.6 | Nb₂O₅ |
| 142 | 74.9 | SiO₂ |
| 143 | 68.5 | Nb₂O₅ |
| 144 | 6.6 | SiO₂ |
| 145 | 29.3 | Nb₂O₅ |
| 146 | 113.9 | SiO₂ |
| 147 | 80.9 | Nb₂O₅ |
| 148 | 40.8 | SiO₂ |
| 149 | 106.8 | Nb₂O₅ |
| 150 | 39.2 | SiO₂ |
| 151 | 35.8 | Nb₂O₅ |
| 152 | 26.0 | SiO₂ |
| 153 | 69.8 | Nb₂O₅ |
| 154 | 63.1 | SiO₂ |
| 155 | 92.9 | Nb₂O₅ |
| 156 | 268.2 | SiO₂ |
| 157 | 18.8 | Nb₂O₅ |
| 158 | 48.8 | SiO₂ |
| 159 | 173.5 | Nb₂O₅ |
| 160 | 233.4 | SiO₂ |
| 161 | 139.1 | Nb₂O₅ |
| 162 | 192.4 | SiO₂ |
| 163 | 38.4 | Nb₂O₅ |
| 164 | 15.0 | SiO₂ |
| 165 | 4.5 | Nb₂O₅ |
| 166 | 116.3 | SiO₂ |
| 167 | 40.0 | Nb₂O₅ |
| 168 | 2.1 | SiO₂ |
| 169 | 142.4 | Nb₂O₅ |
| 170 | 13.1 | SiO₂ |
| 171 | 36.2 | Nb₂O₅ |
| 172 | 180.4 | SiO₂ |
| 173 | 132.2 | Nb₂O₅ |
| 174 | 19.8 | SiO₂ |
| 175 | 7.4 | Nb₂O₅ |
| 176 | 207.1 | SiO₂ |
| 177 | 61.4 | Nb₂O₅ |
| 178 | 82.7 | SiO₂ |
| 179 | 11.5 | Nb₂O₅ |
| 180 | 3.6 | SiO₂ |
| 181 | 81.8 | Nb₂O₅ |
| 182 | 90.6 | SiO₂ |
| 183 | 16.9 | Nb₂O₅ |
| 184 | 6.0 | SiO₂ |
| 185 | 4,638.6 | SiC |

### Example 2: Refrigeration Performances

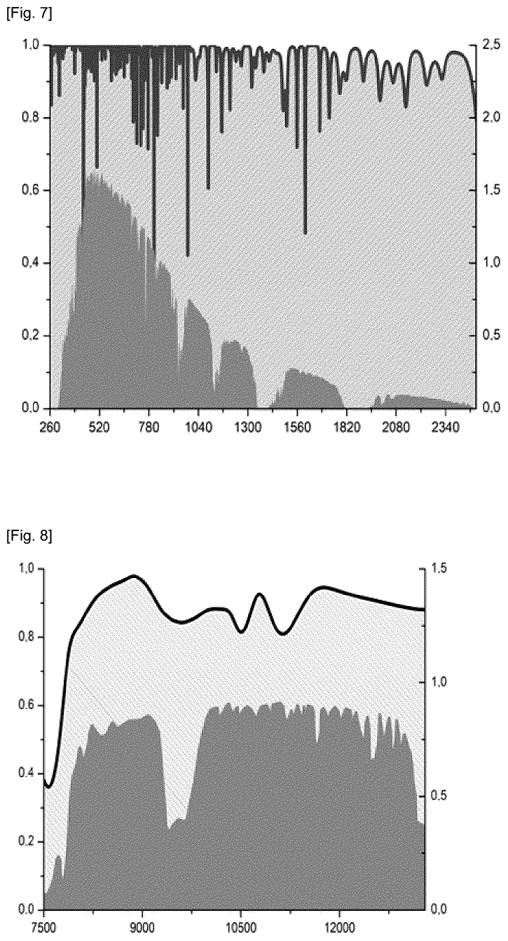

This example discloses the total theoretical reflection and emissivity performances and the associated spectra of the first daytime radiative cooling device determined in Example 1. The reflection spectrum of the wavelengths from 260 nm to 2,500 nm by the daytime radiative device is shown in FIG. 7. The total performance for the reflection of these wavelengths is 97.25% and is obtained using the following formula

$${R}_{AM 1 , 5} = 100 \cdot \frac{{\int }_{{λ}_{min}}^{{λ}_{max}} R ( λ ) {L}_{AM 1 , 5} ( λ ) d λ}{{\int }_{{λ}_{min}}^{{λ}_{max}} {L}_{AM 1 , 5} ( λ ) d λ} \qquad [ Math 38 ]$$

where
λₘₐₓ is 2,500 nm
λₘᵢₙ is 260 nm
R(λ) is the coefficient of reflection of the daytime radiative device obtained for the wavelength λ
L_{AM1.5}(λ)dλ is the radiance of the Sun as a function of the wavelength λ.

The emission spectrum of the wavelengths from 7,500 nm to 13,300 nm by the daytime radiative device is shown in FIG. 8. The total performance for the emissivity of these wavelengths is 89.05% and is obtained using the following formula

$${ϵ}_{AM 1 , 5} = 100 \cdot \frac{{\int }_{{λ}_{min}}^{{λ}_{max}} A ( λ ) {T}_{atm} ( λ ) d λ}{{\int }_{{λ}_{min}}^{{λ}_{max}} {T}_{atm} ( λ ) d λ} \qquad [ Math 39 ]$$

where
λₘₐₓ is 13,300 nm
λₘᵢₙ is 7,500 nm
A(λ) is the absorptivity value for the wavelength λ considering that with the Kirchhoff approximation at thermal equilibrium: α (absorptivity)=ε (emissivity)
Tₐₜₘ(λ)dλ is the atmospheric transmittance as a function of the wavelength A.

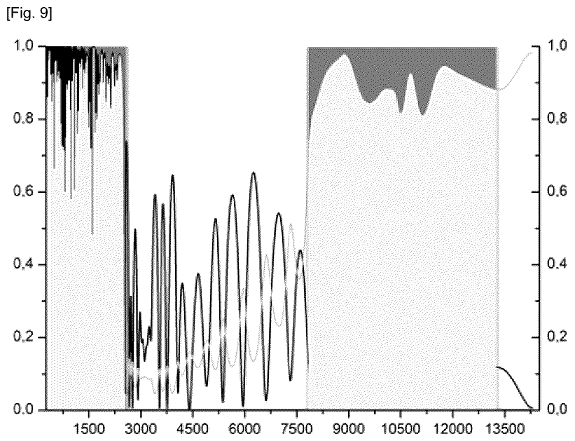

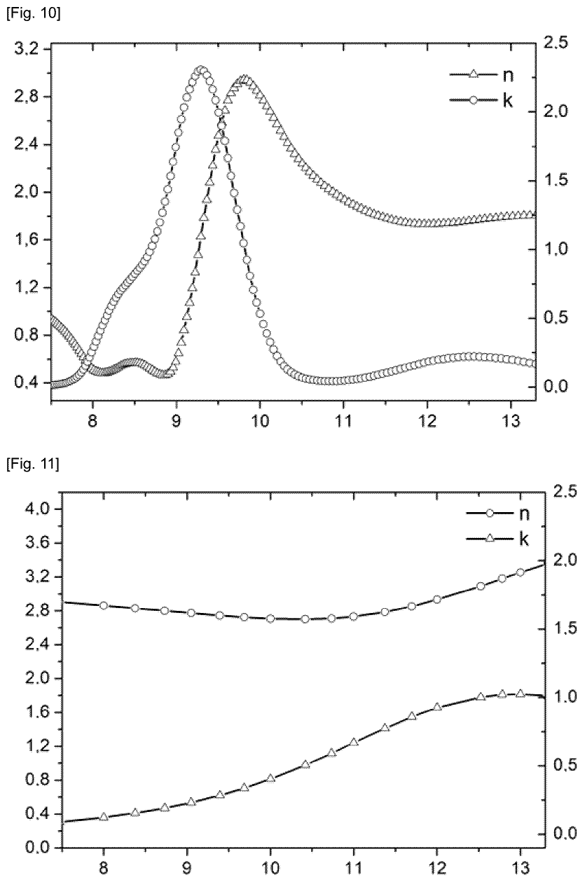

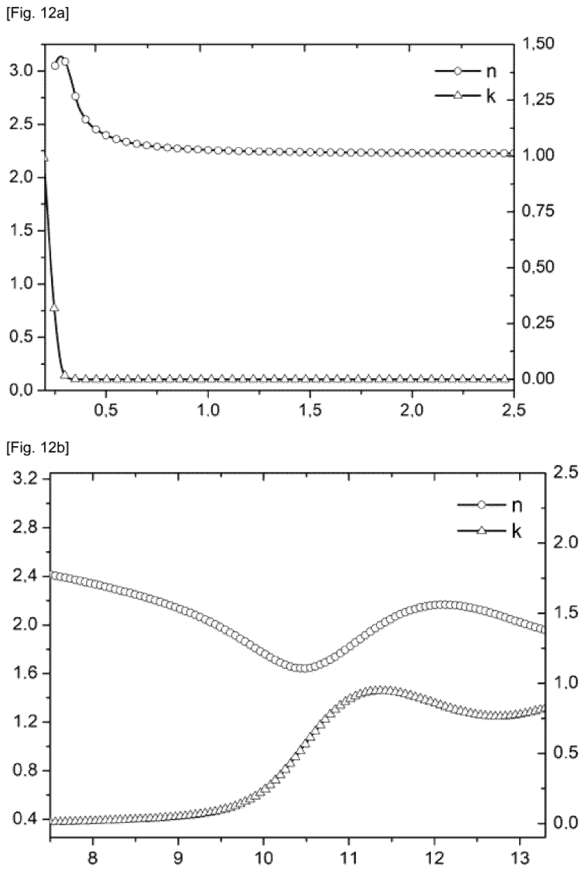

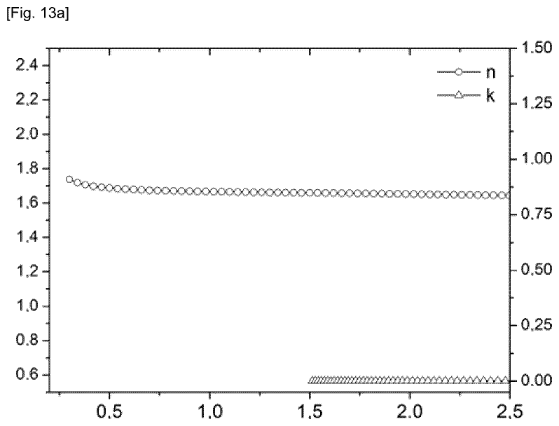

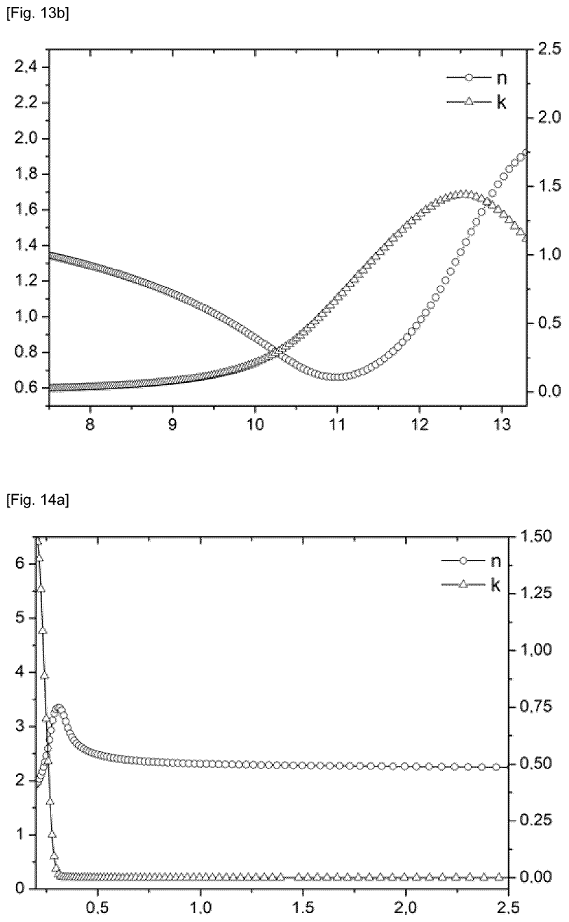

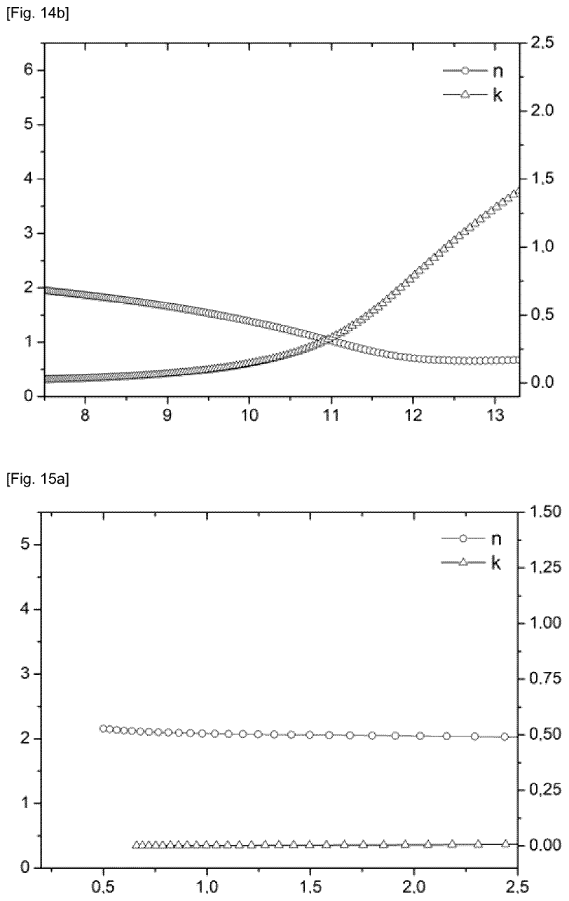

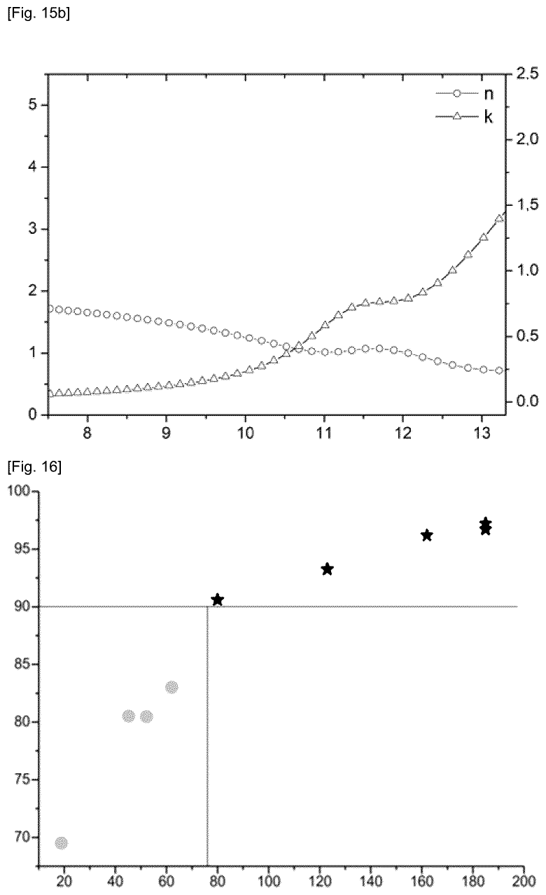

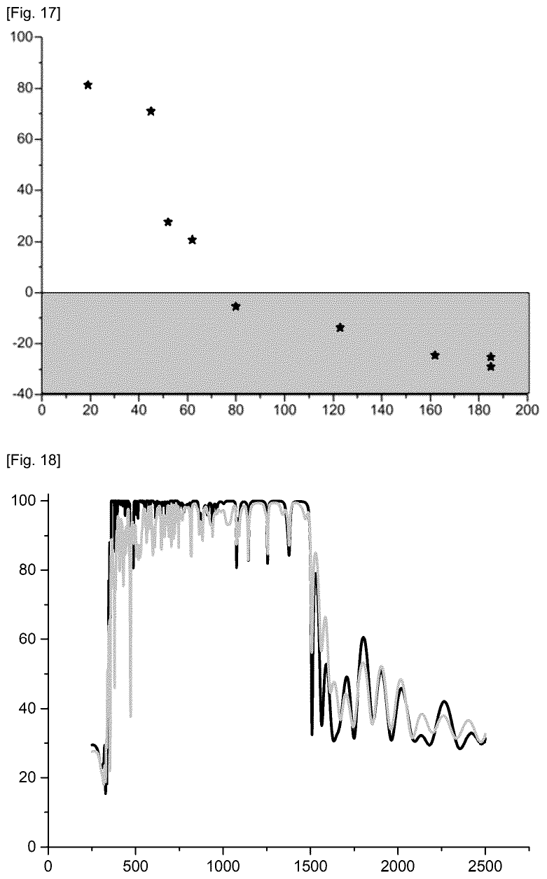

The reflection and emission spectrum of the wavelengths from 260 nm to 15,000 nm is given in FIG. 9.

It should be interestingly noticed that the daytime radiative device of the invention is very effective in terms of reflection and emissivity of the wavelengths in the considered ranges of the spectrum and barely effective, and possibly very barely effective (close to 0), for the rest of the spectrum. This configuration ensures a good heat exchange with the space.

Based on the emissivity and reflection values of the daytime radiative device, the Inventors have determined the equilibrium temperature of said device under the ideal conditions of absence of conduction and convection and under a solar flux of 1,000.3 W·m⁻². For an ambient temperature of 300K (26.85° C.), the equilibrium temperature of the theoretical daytime radiative device is established at 270.99K (−2.16° C.), i.e. a deviation close to 30° C. At the same ambient temperature, the absolute value of the theoretical overall net power of said device is 109.7 W·m⁻². This value is exceptional and corresponds at most to twice the theoretical overall net power (40 W·m²) reached with the device described in the document A. P. Raman et al, Nature, 2014, 515, 540-544 mentioned in the introduction.

### Example 3: Protocol for Manufacturing a Cooling Radiative Device

The deposition of the different layers of the cooling radiative devices disclosed in Example 1 is carried out by magnetron cathode sputtering with optical tracking on an ELETTRORAVA® sputtering machine (ER-SM800) with an Intellemetrics® (IL570) reflectometry system installed inside the deposition chamber. First of all, a numerical simulation of the manufacturing process of the structure to be deposited is carried out using the Film maker software from Intellemetrics®. This allows determining the spectrophotometric tracking configuration of the samples during growth. This configuration allows establishing the wavelength at which each layer of a material will be controlled in reflection, to predict the turning points “turning point” during growth of the film and to predict the conditions for stopping each material.

Afterwards, the preparation of the substrate is carried out chemically, in order to suppress any defects, at the start of the growth of the thin film. A chemical treatment based on hydrofluoric acid with a concentration of 5% is performed for 30 seconds. The substrate is rinsed in 3 baths of ultrapure water for 1 minute each. The substrate is then dried under a stream of pure nitrogen to remove any trace of water.

A Si substrate is introduced into the deposition chamber where the indicated vacuum is 2 mTorr (1 mTorr=0.133322 pascal). The sample (substrate on its substrate holder) will be placed at a temperature whose measurement range will be set between 25° C. and 200° C. This step lasts for one hour at the pressure of 20 mtorr under an argon stream of 10 sccm (standard cubic centimetre per minute), the sample rotating at 20 revolutions per minute. The level of light intensity reflected by the substrate over the previously determined range of wavelengths is controlled.

It has been proceeded with the initiation of the ignition of the plasma. First of all, a working power is injected in several steps on the cathode with an argon pressure of 20 mTorr. This pressure is decreased to 15 m Torr and then to 10 m Torr to finish by a pressure of 5 mtorr always under a stream of 10 sccm of argon. Finally, the stabilisation of the plasma is reached for a deposition of 3 to 5 mTorr with an argon-based gas mixture for the first film. The gas mixture is modified according to the deposited material:
SiC: Argon 100%,
SiO₂: Argon/O₂ with a 75%/25% ratio, and
Nb₂O₅: Argon/O₂ with a 75%/25% ratio.

The first deposited portion is the emitting portion following the established alternation of the materials B and C in the example 1. The optical tracking of the film is carried out in real-time by a measurement of reflection at the wavelengths established before. The deposition time is adjusted during deposition by the thickness growth control system by in situ reflectometry. When the optical stop condition is reached for a material B of the emitter, the deposition thereof is stopped. The following material C is started up to the stop condition thereof. This leads to obtaining the final emitting structure.

Afterwards, the reflective portion is deposited over the emitting portion by following the established alternation of the materials A and B in Example 1. During this step, it is proceeded with a measurement of reflection at the wavelengths previously established by the Intellemetrics system. When the optical stop condition is reached for a material of the reflector, the deposition of the latter is stopped. The next material is started up to the stop condition thereof, and so on until depositing all of the layers and obtaining the reflective structure.

### Example 4: Making and Performance of a Cooling Radiative Device

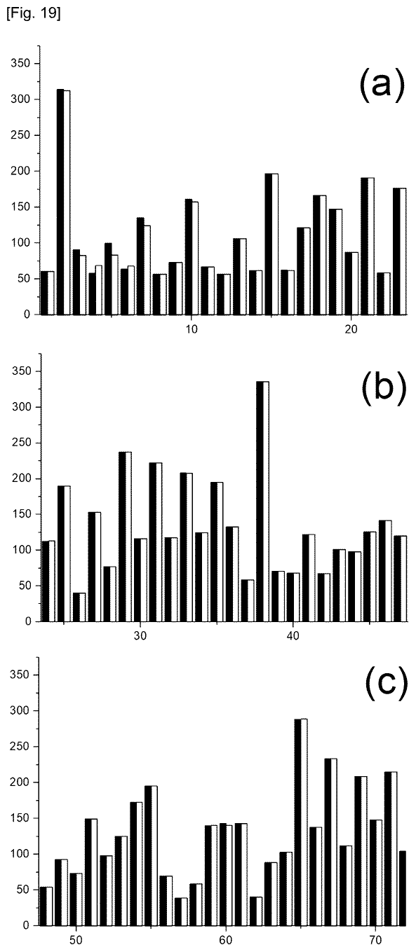

In this example, a daytime radiative device has been made consisting of a reflective portion featuring excellent reflection performances in the spectral range 250-1,500 nm and consisting of an alternation of 72 layers of SiO₂ and Nb₂O₅. The figure of merit of the target reflection performances is shown in FIG. 18. The theoretical thicknesses (shown in FIG. 19) have been obtained by the method for determining the structure of a reflective portion of the invention based on the figure of merit.

The deposition of the different layers has been carried out with the same tooling as that described in Example 3. The steps for obtaining the substrate and stabilising the plasma are the same as those described in Example 3. The Si substrate had a thickness of 275 μm.

A confocal configuration of 3 inch diameter targets made of Nb₂O₅ and SiO₂ has been used. The constituent materials of the targets (Nb₂O₅ and SiO₂) have been sprayed by means of an Oxygen/Argon plasma of 7/37 sccm respectively for the SiO₂ layers and of 12/40 sccm respectively for the Nb₂₀₅ layers. The distance between the targets and the deposition substrate was 20 cm. A power of 100 W and 325 W has been applied respectively for the SiO₂ and Nb₂O₅ targets, which corresponds to a power density on the SiO₂ target of 2.2 W/cm² and on the Nb₂O₅ target of 7.7 W/cm². The deposition rates of the two materials are comprised between 0.01 and 0.1 nm/s. Finally, the deposition pressure was 2 mtorr and the temperature of the substrate was 200° C.

The spectral reflectance of the obtained device has been measured by a Lambda 1050 spectrophotometer (Perkin Elmer®) equipped with a “Universal Reflectance” (URA) module with an angle of incidence of 8° and with transverse electric polarisation (TE). The obtained result is shown in FIG. 18 which shows the reflectance measured by the URA module. This figure shows that the obtained device has a spectral response that is very close to the targeted theoretical reflectance.

FIG. 19 shows for each layer on the one hand the target thickness and on the other hand the experimental thickness determined by the kinetics of deposition of the layers taking into account the deposition rate and the deposition time for each layer. The obtained differences between the target thicknesses and the experimental thicknesses were low with an average difference of 1.78±0.85%.

1. A daytime radiative cooling device comprising a reflective portion for the wavelengths from 260 nm to 2,500 nm consisting of an alternating superposition of layers A and of layers B, said layers A consisting of at least one material A selected from among Nb₂O₅, TiO₂ and Ta₂O₅, said layers B consisting of at least one material B selected from among SiO₂ and Al₂O₃.

2. The device according to claim 1, wherein each layer A and each layer B has a respective and independent thickness from 1 to 1,750 nm.

3. The device according to claim 1, wherein the reflective portion comprises at least 70 layers.

4. The device according to claim 1, further comprising a emitting portion of wavelengths from 7,500 to 13,300 nm comprising at least one layer C consisting of a material C selected from among Nb₂O₅, SiO₂, SiC, TiO₂, Ta₂O₅ and Al₂O₃, the material C being different from the material(s) A and the material(s) B of the reflective portion, the reflective portion being arranged on the emitting portion.

5. The device according to claim 4, wherein the emitting portion comprises at least one superposition of at least one layer C and of at least one layer B, the selected material B and material C being different.

6. The device according to claim 4, wherein all of the layers C have a total thickness of at least 1.5 μm.

7. The device according to claim 1, wherein the structure of the reflective portion is determined by automated means implementing the following steps:
a) providing a base reflection structure, said structure having a thickness and consisting of at least one layer A and/or of at least one layer B, said layer A consisting of a material A selected from among Nb₂O₅, TiO₂ and Ta₂O₅ and said layer B consisting of a material B selected from among SiO₂ and Al₂O₃,
b) determining an improved reflection structure by means of the following sub-steps:
i. selecting a wavelength whose reflection is to be improved, said wavelength being selected from a range of reflection wavelengths from 260 nm to 2,500 nm,
ii. selecting a material to be inserted according to the following criteria:
said material to be inserted is selected from among those of the material B if the base reflection structure consists of a layer A,
said material to be inserted is selected from among those of the material A if the base reflection structure consists of a layer B,
said material to be inserted is selected from among those of the material A or from those of the material B in all other cases,
iii. determining the number of new layers to be inserted into the base reflection structure and their position within the base reflection structure, a new layer consisting of said material to be inserted and inserted according to the thickness of the base reflection structure,
said number and said position being determined according to the selected wavelength and the selected material to be inserted,
iv. determining the thickness of the or each new layer and obtaining an improved reflection structure in which the new layer(s) is/are incorporated,
c) determining a reflection performance value χ_{R} of the improved structure using the following formula
$${χ}_{R} = \frac{1}{\sqrt{N}} \sqrt{{\sum }_{i = 1}^{N} \frac{{( {R}_{SRA} ( {λ}_{i} ) - {R}_{F M} ( {λ}_{i} ) )}^{2}}{{tol}^{2}}}$$
where
λᵢ is a wavelength in the range of reflection wavelengths,
N is the number of spectral wavelengths in the range of reflection wavelengths,
R_{SRA}(λᵢ) is the coefficient of reflection obtained for the improved reflection structure at the wavelength λᵢ,
R_{FM}(λᵢ) is the coefficient of reflection to be reached at the wavelength λᵢ, and tol has a value of 0.1,
d) if χ_{R} has a value lower than or equal to a reference value χ_{Rref}, determining the improved reflection structure as corresponding to the reflective portion of the daytime radiative device; or
if χ_{R} has a value higher than the reference value χ_{Rref}, repeating steps b) to d) while selecting the base reflection structure as being the improved reflection structure determined in step b).

8. The device according to claim 4, wherein the structure of the emitting portion is determined by automated means implementing the following steps:
a) providing a base emissivity structure, said structure having a thickness and consisting of at least one layer C and/or of at least one layer B, said layer C consisting of a material C selected from among Nb₂O₅, SiO₂, SiC, TiO₂, Ta₂O₅ and Al₂O₃ and said layer B consisting of a material B selected from among SiO₂ and Al₂O₃, the material C being different from the material B and different from the material(s) A of the reflective portion,
b) determining an improved emissivity structure by means of the following sub-steps:
i. selecting a wavelength whose reflection is to be improved, said wavelength being selected from a range of reflection wavelengths from 7,500 nm to 13,300 nm,
ii. selecting a material to be inserted according to the following criteria:
said material to be inserted is selected from among those of the material B if the base emissivity structure consists of a layer C,
said material to be inserted is selected from among those of the material C if the base emissivity structure consists of a layer B,
said material to be inserted is selected from among those of the material C or from those of the material B in all other cases,
iii. determining the number of new layers to be inserted into the base emission structure and their position within the base emissivity structure, a new layer consisting of said material to be inserted and inserted according to the thickness of the base emissivity structure,
said number and said position being determined according to the selected wavelength and the selected material to be inserted,
iv. determining the thickness of the or each new layer, and obtaining an improved emissivity structure in which the new layer(s) is/are incorporated,
c) determining an absorption performance value χ_{A} of the improved structure using the following formula
$${χ}_{A} = \frac{1}{\sqrt{N}} \sqrt{{\sum }_{i = 1}^{N} \frac{{( {A}_{SEA} ( {λ}_{i} ) - {A}_{F M} ( {λ}_{i} ) )}^{2}}{{tol}^{2}}}$$
where
λᵢ is a wavelength in the emission wavelength range,
N is the number of wavelengths in the emission wavelength range,
A_{SRA}(λᵢ) is the coefficient of absorption obtained for the improved structure at the spectral wavelength λᵢ,
A_{FM}(λᵢ) is the coefficient of absorption to be reached at the spectral wavelength λᵢ, and tol has a value of 0.1,
d) if χ_{A} has a value lower than or equal to a reference value χ_{Aref}, determining the improved emissivity structure as corresponding to the emitting portion of the daytime radiative device; or
if χ_{A} has a value higher than the reference value (χ_{ref}, repeating steps b) to d) while selecting the base emissivity structure as being the improved emissivity structure determined in step b).

9. A method for determining the structure of the reflective portion of a daytime radiative cooling device according to claim 1, wherein automated means implement the following steps:
a) providing a base reflection structure, said structure having a thickness and consisting of at least one layer A and/or of at least one layer B, said layer A consisting of a material A selected from among Nb₂O₅, TiO₂ and Ta₂O₅ and said layer B consisting of a material B selected from among SiO₂ and Al₂O₃,
b) determining an improved reflection structure by means of the following sub-steps:
i. selecting a wavelength whose reflection is to be improved, said wavelength being selected from a range of reflection wavelengths from 260 nm to 2,500 nm,
ii. selecting a material to be inserted according to the following criteria:
said material to be inserted is selected from among those of the material B if the base reflection structure consists of a layer A,
said material to be inserted is selected from among those of the material A if the base reflection structure consists of a layer B,
said material to be inserted is selected from among those of the material A or from those of the material B in all other cases,
iii. determining the number of new layers to be inserted into the base reflection structure and their position within the base reflection structure, a new layer consisting of said material to be inserted and inserted according to the thickness of the base reflection structure,
said number and said position being determined according to the selected wavelength and the selected material to be inserted,
iv. determining the thickness of the or each new layer, and obtaining an improved reflection structure in which the new layer(s) is/are incorporated,
c) determining a reflection performance value χ_{E} of the improved structure using the following formula
$${χ}_{R} = \frac{1}{\sqrt{N}} \sqrt{{\sum }_{i = 1}^{N} \frac{{( {R}_{SRA} ( {λ}_{i} ) - {R}_{F M} ( {λ}_{i} ) )}^{2}}{{tol}^{2}}}$$
where
λᵢ is a wavelength in the range of reflection wavelengths,
N is the number of spectral wavelengths in the range of reflection wavelengths,
R_{SRA}(λᵢ) is the coefficient of reflection obtained for the improved reflection structure at the spectral wavelength λᵢ,
R_{FM}(λᵢ) is the coefficient of reflection to be reached at the wavelength λᵢ, and tol has a value of 0.1,
d) if χ_{R} has a value lower than or equal to a reference value χ_{Rref}, determining the improved reflection structure as corresponding to the reflective portion of the daytime radiative device; or
if χ_{R} has a value higher than the reference value χ_{Rref}, repeating steps b) to d) while selecting the base reflection structure as being the improved reflection structure determined in step b).

10. A method for determining the emitting portion of a daytime radiative device according to claim 4, wherein automated means implementing the following steps:
a) providing a base emissivity structure, said structure having a thickness and consisting of at least one layer C and/or of at least one layer B, said layer C consisting of a material C selected from among Nb₂O₅, SiO₂, SiC, TiO₂, Ta₂O₅ and Al₂O₃ and said layer B consisting of a material B selected from among SiO₂ and Al₂O₃, the material C being different from the material B,
b) determining an improved emissivity structure by means of the following sub-steps:
i. selecting a wavelength whose reflection is to be improved, said wavelength being selected from a range of reflection wavelengths from 7,500 nm to 13,300 nm,
ii. selecting a material to be inserted according to the following criteria:
said material to be inserted is selected from among those of the material B if the base emissivity structure consists of a layer C,
said material to be inserted is selected from among those of the material C if the base emissivity structure consists of a layer B,
said material to be inserted is selected from among those of the material C or from those of the material B in all other cases,
iii. determining the number of new layers to be inserted into the base emission structure and their position within the base emissivity structure, a new layer consisting of said material to be inserted and inserted according to the thickness of the base emissivity structure,
said number and said position being determined according to the selected wavelength and the selected material to be inserted,
iv. determining the thickness of the or each new layer and obtaining an improved emissivity structure in which the new layer(s) is/are incorporated,
c) determining an absorption performance value χ_{A} of the improved structure using the following formula:
$${χ}_{A} = \frac{1}{\sqrt{N}} \sqrt{{\sum }_{i = 1}^{N} \frac{{( {A}_{SEA} ( {λ}_{i} ) - {A}_{F M} ( {λ}_{i} ) )}^{2}}{{tol}^{2}}}$$
where
λᵢ is a wavelength in the emission wavelength range,
N is the number of wavelengths in the emission wavelength range,
A_{SRA}(λᵢ) is the coefficient of absorption obtained for the improved structure at the spectral wavelength λᵢ,
A_{FM}(λᵢ) is the coefficient of absorption to be reached at the spectral wavelength λᵢ, and tol has a value of 0.1,
d) if χ_{A} has a value lower than or equal to a reference value χ_{Aref}, determining the improved emissivity structure as corresponding to the emitting portion of the daytime radiative device; or
if χ_{A} has a value higher than the reference value χ_{Aref}, repeating steps b) to d) while selecting the base emissivity structure as being the improved emissivity structure determined in step b).
